(19) United States
(12) Patent Application Publication
(10) Pub. No.: US 2024/0349461 A1
(43) Pub. Date: Oct. 17, 2024

(54) AIR-CONDITIONING SYSTEM FOR DATA CENTER COMPUTER ROOM AND CONTROL METHOD THEREOF

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN); Shun WANG, Zhangjiakou City (CN)

(21) Appl. No.: 18/630,103

(22) Filed: Apr. 9, 2024

(30) Foreign Application Priority Data
Apr. 14, 2023 (CN) 202310398745.7

(51) Int. Cl. H05K 7/20

(52) U.S. Cl. CPC H05K 7/20745; H05K 7/20836

(57) ABSTRACT

Embodiments of the present disclosure provide an air-conditioning system for a data center computer room and a control method thereof, belonging to the field of data center technology. The system includes one or more refrigeration subsystems and one or more server clusters, where pipelines of each of the refrigeration subsystem are independent of each other. Each of the refrigeration subsystems includes at least one outdoor refrigeration module and a plurality of indoor heat exchange modules respectively arranged in the server clusters, and the plurality of indoor heat exchange modules are connected in parallel through the pipelines.

### CROSS REFERENCE TO RELATED APPLICATION

This application claims priority to Chinese Patent Application No. 202310398745.7, titled “AIR-CONDITIONING SYSTEM FOR DATA CENTER COMPUTER ROOM AND CONTROL METHOD THEREOF” and filed to the China National Intellectual Property Administration on Apr. 14, 2023, the entire contents of which are incorporated herein by reference.

### TECHNICAL FIELD

The present disclosure relates to the field of data center technology, and more particularly, to an air-conditioning system for a data center computer room and a control method thereof.

### BACKGROUND

With the development of data center scale and integration, power density of server devices in a data center computer room is increasing day by day, and thermal density of the data center is getting higher and higher. In one aspect, power consumption of the data center computer room has increased significantly. In another aspect, cooling adjustment of the data center is not reasonable, such that it is unable to effectively dissipate heat for heating devices, which may lead to device shutdown.

Traditional data center computer rooms adopt mechanical refrigeration to solve the problem of heat dissipation of the data center computer rooms. Mechanical refrigeration consumes a large amount of electrical energy, even accounting for over 35% of total power consumption in data center, and refrigeration effects are poor. At present, indirect evaporative cooling air-conditioning units are generally used in the market to mechanically refrigerate the data center computer rooms.

Inventors of the present disclosure find through research that in the process of refrigeration regulation, the indirect evaporative cooling air-conditioning units not only need to consume a lot of electric energy, but also use a lot of cooling water, and thus consumes a lot of water resources.

### SUMMARY

To solve some or all problems existing in the prior art, embodiments of the present disclosure provide an air-conditioning system for a data center computer room and a control method thereof. The technical solutions are as follows.

In a first aspect, there is provided an air-conditioning system for a data center computer room, including one or more refrigeration subsystems and one or more server clusters. Pipelines of each of the refrigeration subsystem are independent of each other.

Each of the refrigeration subsystems includes at least one outdoor refrigeration module and a plurality of indoor heat exchange modules respectively arranged in the server clusters, and the plurality of indoor heat exchange modules are connected in parallel through the pipelines.

Further, the at least one outdoor refrigeration module includes: a spray cooling unit, an outdoor heat exchange unit, a mechanical refrigeration unit, and an outdoor fan.

The outdoor heat exchange unit is connected to the mechanical refrigeration unit through the pipelines.

The spray cooling unit is arranged adjacent to an outer side of the outdoor heat exchange unit.

The outdoor fan is arranged at an air outlet of the outdoor heat exchange unit.

Further, the mechanical refrigeration unit includes a compressor, a first branch one-way valve, and a second branch one-way valve. The compressor is connected in series with the first branch one-way valve through the pipelines to form a compressor set, and the second branch one-way valve is connected in parallel with the compressor set through the pipelines.

Further, the compressor is a magnetic levitation compressor.

Further, the indoor heat exchange module includes an indoor heat exchanger and an indoor fan.

An inlet pipeline and an outlet pipeline of the indoor heat exchanger are respectively connected to an outlet pipeline and an inlet pipeline of the outdoor refrigeration module.

The indoor fan is arranged at an indoor air channel of the data center computer room.

Further, an electronic expansion valve is connected to the inlet pipeline or the outlet pipeline of the indoor heat exchanger.

A second aspect provides a control method for an air-conditioning system for a data center computer room, where the control method is applied to the air-conditioning system for the data center computer room as described in the first aspect, and the control method includes:
determining a refrigeration mode based on an indoor ambient temperature of the data center computer room, where the refrigeration mode includes a natural refrigeration mode and a mechanical refrigeration mode;
determining number of the refrigeration subsystems based on a size of each of the server clusters; and
determining number of the indoor heat exchange modules in each of the refrigeration subsystems based on number of the server clusters.

Further, the determining a refrigeration mode based on an indoor ambient temperature of the data center computer room includes:
enabling the natural refrigeration mode when the indoor ambient temperature of the data center is not higher than a preset temperature threshold; and
enabling the mechanical refrigeration mode when the indoor ambient temperature of the data center is higher than the preset temperature threshold in the natural refrigeration mode.

Further, the determining number of the refrigeration subsystems based on a size of each of the server clusters includes:
increasing the number of the refrigeration subsystems when number of servers in a target server cluster increases.

Further, the determining number of the indoor heat exchange modules in each of the refrigeration subsystems based on number of the server clusters includes:
increasing the number of the indoor heat exchange modules connected in parallel in each of the refrigeration subsystems when the number of the server clusters increases.

The present disclosure carries out modular management on the air-conditioning system for the data center computer room, which can provide cold sources according to actual heat dissipation needs of different areas of the data center computer room, flexibly and accurately allocate refrigeration capacity, and meet requirements of business volume changes in the servers of the computer room. Consumption of water resources can be reduced by means of spray cooling. Energy can be saved by cooling the servers using natural cooling sources. Each refrigeration subsystem operates independently and serves as mutual standby, which can reduce a risk of server outage and improve reliability of operation of the computer room. Temperature of each row of servers can be independently controlled to eliminate hotspots in the computer room. A refrigeration terminal is independently arranged for easy maintenance.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of an air-conditioning system for a data center computer room provided by an embodiment of the present disclosure;

FIG. 2 is a schematic structural diagram of the system when a single refrigeration subsystem provided by an embodiment of the present disclosure cools a plurality of server clusters;

FIG. 3 is a schematic structural diagram of the system when two refrigeration subsystems provided by an embodiment of the present disclosure cools the plurality of server clusters;

FIG. 4 is a schematic structural diagram of the system when three refrigeration subsystems provided by an embodiment of the present disclosure cools the plurality of server clusters;

FIG. 5 is a schematic structural diagram of the system when a plurality of refrigeration subsystems provided by an embodiment of the present disclosure cools a single server cluster;

FIG. 6 is a schematic structural diagram of the system when the plurality of refrigeration subsystems provided by an embodiment of the present disclosure cools two server clusters; and

FIG. 7 is a schematic structural diagram of the system when the plurality of refrigeration subsystems provided by an embodiment of the present disclosure cools three server clusters.

### DETAILED DESCRIPTION

To make the objectives, technical solutions and advantages of the present disclosure clearer, the embodiments of the present disclosure will be further described below in detail with reference to the accompanying drawings. Terms such as “upper”, “above”, “lower”, “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “slidably connected”, “fixed” and “sleeved” should be understood in a broad sense. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

The present disclosure provides an air-conditioning system for a data center computer room, including one or more refrigeration subsystems and one or more server clusters. Pipelines of each of the refrigeration subsystem are independent of each other.

Each of the refrigeration subsystems includes at least one outdoor refrigeration module and a plurality of indoor heat exchange modules respectively arranged in the server clusters, and the plurality of indoor heat exchange modules are connected in parallel through the pipelines.

In one embodiment, the at least one outdoor refrigeration module includes: a spray cooling unit, an outdoor heat exchange unit, a mechanical refrigeration unit, and an outdoor fan.

The outdoor heat exchange unit is connected to the mechanical refrigeration unit through the pipelines.

The spray cooling unit is arranged adjacent to an outer side of the outdoor heat exchange unit to cool the outdoor heat exchange unit.

The outdoor fan is arranged at an air outlet of the outdoor heat exchange unit.

In one embodiment, the mechanical refrigeration unit includes a compressor, a first branch one-way valve, and a second branch one-way valve. The compressor is connected in series with the first branch one-way valve through the pipelines to form a compressor set, and the second branch one-way valve is connected in parallel with the compressor set through the pipelines.

In one embodiment, the compressor is a magnetic levitation compressor.

Compared with traditional air compressors, the magnetic levitation air compressor does not require lubricating oil, has lower vibration and lower noise, and is more energy-efficient.

In one embodiment, the indoor heat exchange module includes an indoor heat exchanger and an indoor fan.

An inlet pipeline and an outlet pipeline of the indoor heat exchanger are respectively connected to an outlet pipeline and an inlet pipeline of the outdoor refrigeration module.

The indoor fan is arranged at an indoor air channel of the data center computer room.

Further, an electronic expansion valve is connected to the inlet pipeline or the outlet pipeline of the indoor heat exchanger.

In one embodiment, each refrigeration subsystem is comprised of a spray cooling system, a condenser, an outdoor fan, a liquid reservoir, a refrigerant circulating pump, a plurality of electronic expansion valves, a plurality of evaporators, a plurality of indoor fans, a magnetic suspension centrifugal compressor, a one-way valve, and refrigeration pipelines, etc.

It is to be understood that a server cluster refers to a collection of a plurality of computer devices gathered together to provide a certain cluster service.

The evaporator may be an evaporative condenser.

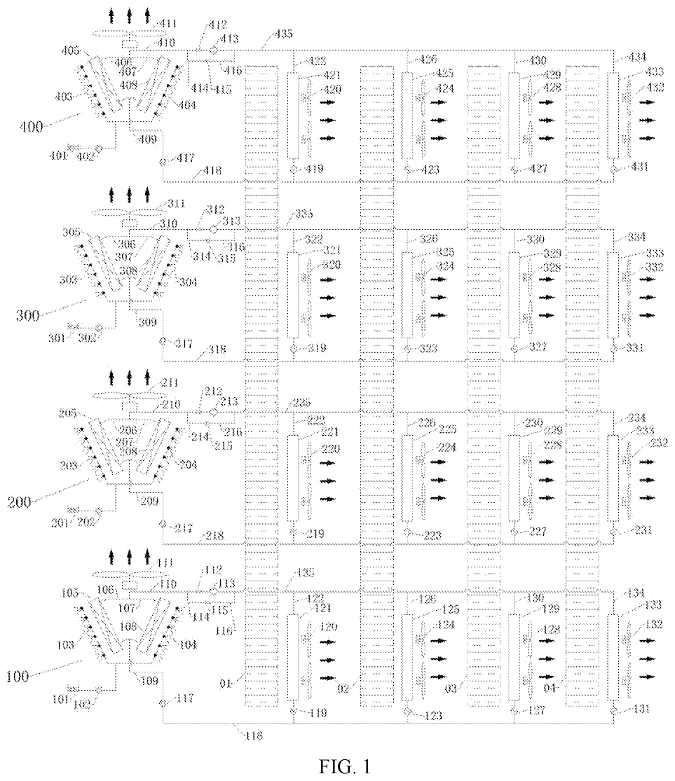

Referring to FIG. 1, in one embodiment, the air-conditioning system for the data center computer room includes server clusters 01 to 04 and refrigeration subsystems 100 to 400.

The refrigeration subsystem 100 includes: a water tank 101, a water pump 102, spray components 103 and 104 and connection pipelines of the spray cooling system; an outdoor heat exchange fan 111; outdoor heat exchangers 105 and 108; outdoor heat exchanger air inlet pipelines 106 and 107; an outdoor heat exchanger liquid outlet pipeline 109; a refrigerant circulating pump 117; a refrigerant circulating pump liquid outlet pipe 118; indoor electronic expansion valves 119, 123, 127 and 131; where after throttling, the refrigerant enters indoor heat exchangers 121, 125, 129 and 133 through the pipelines; indoor heat exchange fans 120, 124, 128 and 132; indoor heat exchanger return air pipelines 122, 126, 130 and 134; and a main return air pipeline 135, a magnetic suspension compressor 113, a first branch one-way valve 112, a second branch air inlet pipe 116, a second one-way valve 115, a second air outlet pipeline 114, and an outdoor condenser air inlet pipeline 110.

Further, the refrigeration subsystem 200 includes: a water tank 201, a water pump 202, spray components 203 and 204 and connection pipelines of the spray cooling system; an outdoor heat exchange fan 211; outdoor heat exchangers 205 and 208; outdoor heat exchanger air inlet pipelines 206 and 207; an outdoor heat exchanger liquid outlet pipeline 209; a refrigerant circulating pump 217; a refrigerant circulating pump liquid outlet pipe 218; indoor electronic expansion valves 219, 223, 227 and 231; where after throttling, the refrigerant enters indoor heat exchangers 221, 225, 229 and 233 through the pipelines; indoor heat exchange fans 220, 224, 228 and 232; indoor heat exchanger return air pipelines 222, 226, 230 and 234; and a main return air pipeline 235, a magnetic suspension compressor 213, a first branch one-way valve 212, a second branch air inlet pipe 216, a second one-way valve 215, a second air outlet pipeline 214, and an outdoor condenser air inlet pipeline 210.

Further, the refrigeration subsystem 300 includes: a water tank 301, a water pump 302, spray components 303 and 304 and connection pipelines of the spray cooling system; an outdoor heat exchange fan 311; outdoor heat exchangers 305 and 308; outdoor heat exchanger air inlet pipelines 306 and 307; an outdoor heat exchanger liquid outlet pipeline 309; a refrigerant circulating pump 317; a refrigerant circulating pump liquid outlet pipe 318; indoor electronic expansion valves 319, 323, 327 and 331; where after throttling, the refrigerant enters indoor heat exchangers 321, 325, 329 and 333 through the pipelines; indoor heat exchange fans 320, 324, 328 and 332; indoor heat exchanger return air pipelines 322, 326, 330 and 334; and a main return air pipeline 335, a magnetic suspension compressor 313, a first branch one-way valve 312, a second branch air inlet pipe 316, a second one-way valve 315, a second air outlet pipeline 314, and an outdoor condenser air inlet pipeline 310.

Further, the refrigeration subsystem 400 includes: a water tank 401, a water pump 402, spray components 403 and 404 and connection pipelines of the spray cooling system; an outdoor heat exchange fan 411; outdoor heat exchangers 405 and 408; outdoor heat exchanger air inlet pipelines 406 and 407; an outdoor heat exchanger liquid outlet pipeline 409; a refrigerant circulating pump 417; a refrigerant circulating pump liquid outlet pipe 418; indoor electronic expansion valves 419, 423, 427 and 431; where after throttling, the refrigerant enters indoor heat exchangers 421, 425, 429 and 433 through the pipelines; indoor heat exchange fans 420, 424, 428 and 432; indoor heat exchanger return air pipelines 422, 426, 430 and 434; and a main return air pipeline 435, a magnetic suspension compressor 413, a first branch one-way valve 412, a second branch air inlet pipe 416, a second one-way valve 415, a second air outlet pipeline 414, and an outdoor condenser air inlet pipeline 410.

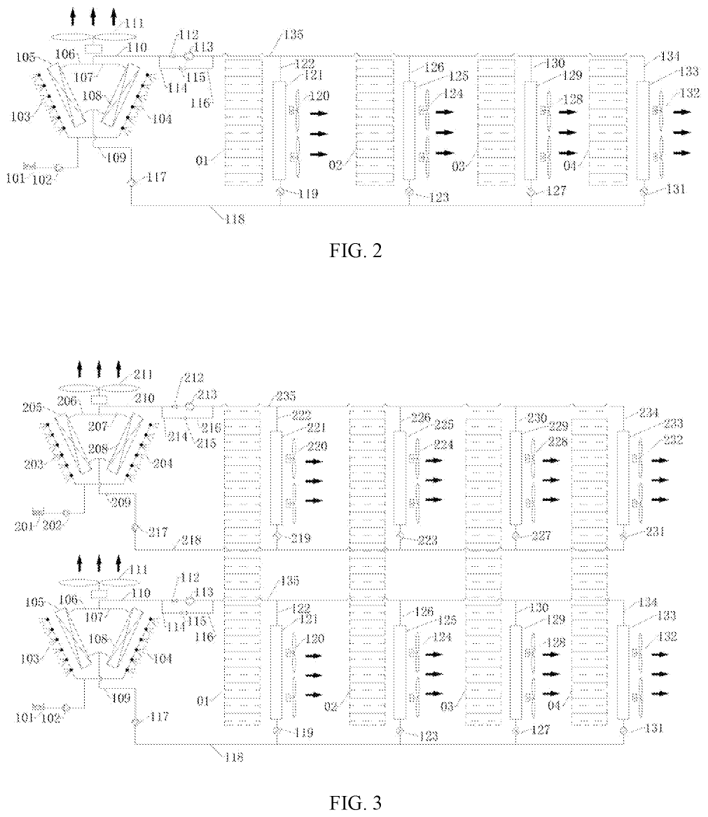

In one embodiment, reference is made to FIG. 2. Driven by the indoor heat exchange fans 120, 124, 128 and 132, heat from the server clusters 01, 02, 03 and 04 in the data center computer room passes through the indoor heat exchangers 121, 125, 129 and 133, and exchanges heat with the refrigerant evaporated after throttling, then flows out of indoor heat exchange channels of the indoor heat exchangers 121, 125, 129 and 133, and then is sent to the computer room through an indoor air supply channel to cool the server clusters 01, 02, 03, and 04. Refrigerant gas evaporated in the indoor heat exchangers flows through the indoor heat exchanger return air pipelines 122, 126, 130 and 134, flows into the air inlet pipeline 116 and the second one-way valve 115 through the main return air pipeline 135, then flows into the outdoor condenser air inlet pipeline 110 through the pipeline 114, then passes through the outdoor heat exchanger air inlet pipelines 106 and 107 respectively, and enters the outdoor finned heat exchangers 105 and 108. By adjusting the outdoor heat exchange fan 111, the refrigerant in the outdoor heat exchangers is cooled, and heat of the refrigerant is discharged into atmosphere, such that the cooled refrigerant changes from gas to liquid. Further, the spray cooling system pressurizes water in the water tank 101 through the water pump 102 and then sends the pressurized water into the spray components 103 and 104, to cool the outdoor heat exchangers 105 and 108, respectively. The cooled refrigerant enters a main refrigerant liquid pipeline 109 through the outdoor heat exchanger liquid outlet pipeline. After being regulated and pressurized by the refrigerant circulating pump 117, the cooled refrigerant is sent through the refrigerant circulating pump liquid outlet pipe 118 to the electronic expansion valves 119, 123, 127, and 131 for throttling. The throttled refrigerant enters the indoor heat exchangers 121, 125, 129 and 133 for evaporation through a throttled refrigerant distribution pipeline again, and then the evaporated refrigerant enters the main return air pipeline 135 again through the return air pipelines 122, 126, 130, and 134. In this way, a complete refrigeration cycle is formed. The outdoor heat exchange fan 111 and the indoor heat exchange fans 120, 124, 128 and 132 may be adjusted respectively according to indoor load of the data center computer room, to obtain a stable indoor target temperature, thereby reducing power consumption of the outdoor and indoor heat exchange fans. The required indoor target temperature can be obtained by means of natural cooling without starting the compressor, thus saving energy consumption.

Further, the heat from the server clusters 01, 02, 03 and 04 in the data center computer room increases. For example, when the indoor ambient temperature reaches a preset temperature, driven by the indoor heat exchange fans 120, 124, 128 and 132, the heat passes through the indoor heat exchangers 121, 125, 129 and 133, and exchanges heat with the refrigerant evaporated after throttling, then flows out of the indoor heat exchange channels of the indoor heat exchangers 121, 125, 129 and 133, and then is sent to the computer room through the indoor air supply channel to cool the server clusters 01, 02, 03, and 04. The refrigerant gas evaporated in the indoor heat exchangers flows through the indoor heat exchanger return air pipelines 122, 126, 130 and 134, flows into the magnetic levitation compressor 113 through the main return air pipeline 135, then enters the first one-way valve 112 after compression, then enters the outdoor condenser air inlet pipeline 110, then passes through the outdoor heat exchanger air inlet pipelines 106 and 107 respectively, and then enters the outdoor finned heat exchangers 105 and 108. By adjusting the outdoor heat exchange fan 111, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 101 through the water pump 102 and then sends the pressurized water into the spray components 103 and 104, to cool the outdoor heat exchangers 105 and 108, respectively. The cooled refrigerant enters the main refrigerant liquid pipeline 109 through the outdoor heat exchanger liquid outlet pipeline. After being regulated and pressurized by the refrigerant circulating pump 117, the cooled refrigerant is sent through the refrigerant circulating pump liquid outlet pipe 118 to the electronic expansion valves 119, 123, 127, and 131 for throttling. The throttled refrigerant enters the indoor heat exchangers 121, 125, 129 and 133 for evaporation through the throttled refrigerant distribution pipeline again, and then the evaporated refrigerant enters the main return air pipeline 135 again through the return air pipelines 122, 126, 130, and 134. In this way, a complete refrigeration cycle is formed. The outdoor heat exchange fan 111 and the indoor heat exchange fans 120, 124, 128 and 132 may be adjusted respectively according to the indoor load of the data center computer room, to obtain the stable indoor target temperature, thereby reducing the power consumption of the outdoor and indoor heat exchange fans. The magnetic levitation centrifugal compressor only needs to work for a small amount of time in a high-temperature environment, thus saving energy consumption.

In one embodiment, referring to FIG. 3, number of the servers in the server clusters 01, 02, 03 and 04 from the data center computer room increases, and heat generated by the servers also increases. Driven by the indoor heat exchange fans 120, 124, 128 and 132, the heat passes through the indoor heat exchangers 121, 125, 129 and 133, and exchanges heat with the refrigerant evaporated after throttling, then flows out of the indoor heat exchange channels of the indoor heat exchangers 121, 125, 129 and 133, and then is sent to the computer room through the indoor air supply channel to cool the server clusters 01, 02, 03, and 04. The refrigerant gas evaporated in the indoor heat exchangers flows through the indoor heat exchanger return air pipelines 122, 126, 130 and 134, flows into the air inlet pipeline 116 and the second one-way valve 115 through the main return air pipeline 135, then flows into the outdoor condenser air inlet pipeline 110 through the pipeline 114, then passes through the outdoor heat exchanger air inlet pipelines 106 and 107 respectively, and enters the outdoor finned heat exchangers 105 and 108. By adjusting the outdoor heat exchange fan 111, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 101 through the water pump 102 and then sends the pressurized water into the spray components 103 and 104, to cool the outdoor heat exchangers 105 and 108, respectively. The cooled refrigerant enters the main refrigerant liquid pipeline 109 through the outdoor heat exchanger liquid outlet pipeline. After being regulated and pressurized by the refrigerant circulating pump 117, the cooled refrigerant is sent through the refrigerant circulating pump liquid outlet pipe 118 to the electronic expansion valves 119, 123, 127, and 131 for throttling. The throttled refrigerant enters the indoor heat exchangers 121, 125, 129 and 133 for evaporation through the throttled refrigerant distribution pipeline again, and then the evaporated refrigerant enters the main return air pipeline 135 again through the return air pipelines 122, 126, 130, and 134. In this way, a complete refrigeration cycle is formed. The outdoor heat exchange fan 111 and the indoor heat exchange fans 120, 124, 128 and 132 may be adjusted respectively according to indoor load of the data center computer room.

Further, driven by the indoor heat exchange fans 220, 224, 228 and 232, the heat passes through the indoor heat exchangers 221, 225, 229 and 233, and exchanges heat with the refrigerant evaporated after throttling, then flows out of the indoor heat exchange channels of the indoor heat exchangers 221, 225, 229 and 233, and then is sent to the computer room through the indoor air supply channel to cool the server clusters 01, 02, 03, and 04. The refrigerant gas evaporated in the indoor heat exchangers flows through the indoor heat exchanger return air pipelines 222, 226, 230 and 234, flows into the air inlet pipeline 216 and the second one-way valve 215 through the main return air pipeline 235, then flows into the outdoor condenser air inlet pipeline 210 through the pipeline 214, then passes through the outdoor heat exchanger air inlet pipelines 206 and 207 respectively, and enters the outdoor finned heat exchangers 205 and 208. By adjusting the outdoor heat exchange fan 211, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 201 through the water pump 202 and then sends the pressurized water into the spray components 203 and 204, to cool the outdoor heat exchangers 205 and 208, respectively. The cooled refrigerant enters the main refrigerant liquid pipeline 209 through the outdoor heat exchanger liquid outlet pipeline. After being regulated and pressurized by the refrigerant circulating pump 217, the cooled refrigerant is sent through the refrigerant circulating pump liquid outlet pipe 218 to the electronic expansion valves 219, 223, 227, and 231 for throttling. The throttled refrigerant enters the indoor heat exchangers 221, 225, 229 and 233 for evaporation through the throttled refrigerant distribution pipeline again, and then the evaporated refrigerant enters the main return air pipeline 235 again through the return air pipelines 222, 226, 230, and 234. In this way, a complete refrigeration cycle is formed. The outdoor heat exchange fan 211 and the indoor heat exchange fans 220, 224, 228 and 232 may be adjusted respectively according to the indoor load of the data center computer room, to obtain the stable indoor target temperature, thereby reducing the power consumption of the outdoor and indoor heat exchange fans. The required indoor target temperature can be obtained by means of natural cooling without starting the compressor, thus saving energy consumption.

Further, the number of the servers in the server clusters 01, 02, 03 and 04 from the data center computer room increases, and heat generated by the servers also increases. Driven by the indoor heat exchange fans 120, 124, 128 and 132, the heat passes through the indoor heat exchangers 121, 125, 129 and 133, and exchanges heat with the refrigerant evaporated after throttling, then flows out of the indoor heat exchange channels of the indoor heat exchangers 121, 125, 129 and 133, and then is sent to the computer room through the indoor air supply channel to cool the server clusters 01, 02, 03, and 04. The refrigerant gas evaporated in the indoor heat exchangers flows through the indoor heat exchanger return air pipelines 122, 126, 130 and 134, flows into the magnetic levitation compressor 113 through the main return air pipeline 135, then enters the first one-way valve 112 after compression, then enters the outdoor condenser air inlet pipeline 110, then passes through the outdoor heat exchanger air inlet pipelines 106 and 107 respectively, and then enters the outdoor finned heat exchangers 105 and 108. By adjusting the outdoor heat exchange fan 111, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 101 through the water pump 102 and then sends the pressurized water into the spray components 103 and 104, to cool the outdoor heat exchangers 105 and 108, respectively. The cooled refrigerant enters the main refrigerant liquid pipeline 109 through the outdoor heat exchanger liquid outlet pipeline. After being regulated and pressurized by the refrigerant circulating pump 117, the cooled refrigerant is sent through the refrigerant circulating pump liquid outlet pipe 118 to the electronic expansion valves 119, 123, 127, and 131 for throttling. The throttled refrigerant enters the indoor heat exchangers 121, 125, 129 and 133 for evaporation through the throttled refrigerant distribution pipeline again, and then the evaporated refrigerant enters the main return air pipeline 135 again through the return air pipelines 122, 126, 130, and 134. In this way, a complete refrigeration cycle is formed. The outdoor heat exchange fan 111 and the indoor heat exchange fans 120, 124, 128 and 132 may be adjusted respectively according to the indoor load of the data center computer room.

Further, driven by the indoor heat exchange fans 220, 224, 228 and 232, the heat passes through the indoor heat exchangers 221, 225, 229 and 233, and exchanges heat with the refrigerant evaporated after throttling, then flows out of the indoor heat exchange channels of the indoor heat exchangers 221, 225, 229 and 233, and then is sent to the computer room through the indoor air supply channel to cool the server clusters 01, 02, 03, and 04. The refrigerant gas evaporated in the indoor heat exchangers flows through the indoor heat exchanger return air pipelines 222, 226, 230 and 234, flows into the magnetic levitation compressor 213 through the main return air pipeline 235, then enters the first one-way valve 212 after compression, then enters the outdoor condenser air inlet pipeline 210, then passes through the outdoor heat exchanger air inlet pipelines 206 and 207 respectively, and then enters the outdoor finned heat exchangers 205 and 208. By adjusting the outdoor heat exchange fan 211, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 201 through the water pump 202 and then sends the pressurized water into the spray components 203 and 204, to cool the outdoor heat exchangers 205 and 208, respectively. The cooled refrigerant enters the main refrigerant liquid pipeline 209 through the outdoor heat exchanger liquid outlet pipeline. After being regulated and pressurized by the refrigerant circulating pump 217, the cooled refrigerant is sent through the refrigerant circulating pump liquid outlet pipe 218 to the electronic expansion valves 219, 223, 227, and 231 for throttling. The throttled refrigerant enters the indoor heat exchangers 221, 225, 229 and 233 for evaporation through the throttled refrigerant distribution pipeline again, and then the evaporated refrigerant enters the main return air pipeline 235 again through the return air pipelines 222, 226, 230, and 234. In this way, a complete refrigeration cycle is formed. The outdoor heat exchange fan 211 and the indoor heat exchange fans 220, 224, 228 and 232 may be adjusted respectively according to the indoor load of the data center computer room, to obtain the stable indoor target temperature, thereby reducing the power consumption of the outdoor and indoor heat exchange fans. The magnetic levitation centrifugal compressor only needs to work for a small amount of time in a high-temperature environment, thus saving energy consumption.

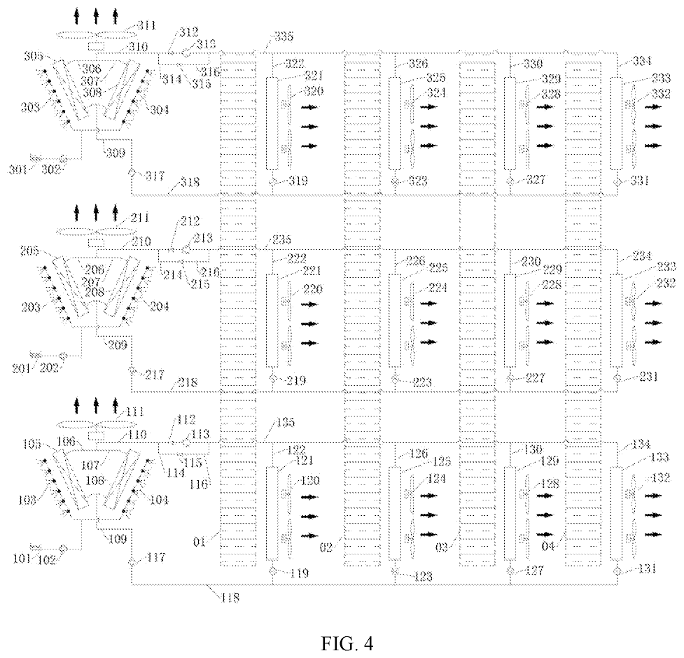

In one embodiment, reference is made to FIG. 4. The number of the servers in the server clusters 01, 02, 03 and 04 from the data center computer room increases, and the heat generated by the servers also increases. Driven by the indoor heat exchange fans 120, 124, 128 and 132, the heat passes through the indoor heat exchangers 121, 125, 129 and 133, and exchanges heat with the refrigerant evaporated after throttling, then flows out of the indoor heat exchange channels of the indoor heat exchangers 121, 125, 129 and 133, and then is sent to the computer room through the indoor air supply channel to cool the server clusters 01, 02, 03, and 04. The refrigerant gas evaporated in the indoor heat exchangers flows through the indoor heat exchanger return air pipelines 122, 126, 130 and 134, flows into the air inlet pipeline 116 and the second one-way valve 115 through the main return air pipeline 135, then flows into the outdoor condenser air inlet pipeline 110 through the pipeline 114, then passes through the outdoor heat exchanger air inlet pipelines 106 and 107 respectively, and enters the outdoor finned heat exchangers 105 and 108. By adjusting the outdoor heat exchange fan 111, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 101 through the water pump 102 and then sends the pressurized water into the spray components 103 and 104, to cool the outdoor heat exchangers 105 and 108, respectively. The cooled refrigerant enters the main refrigerant liquid pipeline 109 through the outdoor heat exchanger liquid outlet pipeline. After being regulated and pressurized by the refrigerant circulating pump 117, the cooled refrigerant is sent through the refrigerant circulating pump liquid outlet pipe 118 to the electronic expansion valves 119, 123, 127, and 131 for throttling. The throttled refrigerant enters the indoor heat exchangers 121, 125, 129 and 133 for evaporation through the throttled refrigerant distribution pipeline again, and then the evaporated refrigerant enters the main return air pipeline 135 again through the return air pipelines 122, 126, 130, and 134. In this way, a complete refrigeration cycle is formed. The outdoor heat exchange fan 111 and the indoor heat exchange fans 120, 124, 128 and 132 may be adjusted respectively according to indoor load of the data center computer room.

Further, driven by the indoor heat exchange fans 220, 224, 228 and 232, the heat passes through the indoor heat exchangers 221, 225, 229 and 233, and exchanges heat with the refrigerant evaporated after throttling, then flows out of the indoor heat exchange channels of the indoor heat exchangers 221, 225, 229 and 233, and then is sent to the computer room through the indoor air supply channel to cool the server clusters 01, 02, 03, and 04. The refrigerant gas evaporated in the indoor heat exchangers flows through the indoor heat exchanger return air pipelines 222, 226, 230 and 234, flows into the air inlet pipeline 216 and the second one-way valve 215 through the main return air pipeline 235, then flows into the outdoor condenser air inlet pipeline 210 through the pipeline 214, then passes through the outdoor heat exchanger air inlet pipelines 206 and 207 respectively, and enters the outdoor finned heat exchangers 205 and 208. By adjusting the outdoor heat exchange fan 211, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 201 through the water pump 202 and then sends the pressurized water into the spray components 203 and 204, to cool the outdoor heat exchangers 205 and 208, respectively. The cooled refrigerant enters the main refrigerant liquid pipeline 209 through the outdoor heat exchanger liquid outlet pipeline. After being regulated and pressurized by the refrigerant circulating pump 217, the cooled refrigerant is sent through the refrigerant circulating pump liquid outlet pipe 218 to the electronic expansion valves 219, 223, 227, and 231 for throttling. The throttled refrigerant enters the indoor heat exchangers 221, 225, 229 and 233 for evaporation through the throttled refrigerant distribution pipeline again, and then the evaporated refrigerant enters the main return air pipeline 235 again through the return air pipelines 222, 226, 230, and 234. In this way, a complete refrigeration cycle is formed. The outdoor heat exchange fan 211 and the indoor heat exchange fans 220, 224, 228 and 232 may be adjusted respectively according to the indoor load of the data center computer room.

Further, driven by the indoor heat exchange fans 320, 324, 328 and 332, the heat passes through the indoor heat exchangers 321, 325, 329 and 333, and exchanges heat with the refrigerant evaporated after throttling, then flows out of the indoor heat exchange channels of the indoor heat exchangers 321, 325, 329 and 333, and then is sent to the computer room through the indoor air supply channel to cool the server clusters 01, 02, 03, and 04. The refrigerant gas evaporated in the indoor heat exchangers flows through the indoor heat exchanger return air pipelines 322, 326, 330 and 334, flows into the air inlet pipeline 316 and the second one-way valve 315 through the main return air pipeline 335, then flows into the outdoor condenser air inlet pipeline 310 through the pipeline 314, then passes through the outdoor heat exchanger air inlet pipelines 306 and 307 respectively, and enters the outdoor finned heat exchangers 305 and 308. By adjusting the outdoor heat exchange fan 311, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 301 through the water pump 302 and then sends the pressurized water into the spray components 303 and 304, to cool the outdoor heat exchangers 305 and 308, respectively. The cooled refrigerant enters the main refrigerant liquid pipeline 309 through the outdoor heat exchanger liquid outlet pipeline. After being regulated and pressurized by the refrigerant circulating pump 317, the cooled refrigerant is sent through the refrigerant circulating pump liquid outlet pipe 318 to the electronic expansion valves 319, 323, 327, and 331 for throttling. The throttled refrigerant enters the indoor heat exchangers 321, 325, 329 and 333 for evaporation through the throttled refrigerant distribution pipeline again, and then the evaporated refrigerant enters the main return air pipeline 335 again through the return air pipelines 322, 326, 330, and 334. In this way, a complete refrigeration cycle is formed. The outdoor heat exchange fan 211 and the indoor heat exchange fans 320, 324, 328 and 332 may be adjusted respectively according to the indoor load of the data center computer room, to obtain the stable indoor target temperature, thereby reducing the power consumption of the outdoor and indoor heat exchange fans. The required indoor target temperature can be obtained by means of natural cooling without starting the compressor, thus saving energy consumption.

Further, the number of the servers in the server clusters 01, 02, 03 and 04 from the data center computer room increases, and heat generated by the servers also increases. Driven by the indoor heat exchange fans 120, 124, 128 and 132, the heat passes through the indoor heat exchangers 121, 125, 129 and 133, and exchanges heat with the refrigerant evaporated after throttling, then flows out of the indoor heat exchange channels of the indoor heat exchangers 121, 125, 129 and 133, and then is sent to the computer room through the indoor air supply channel to cool the server clusters 01, 02, 03, and 04. The refrigerant gas evaporated in the indoor heat exchangers flows through the indoor heat exchanger return air pipelines 122, 126, 130 and 134, flows into the magnetic levitation compressor 113 through the main return air pipeline 135, then enters the first one-way valve 112 after compression, then enters the outdoor condenser air inlet pipeline 110, then passes through the outdoor heat exchanger air inlet pipelines 106 and 107 respectively, and then enters the outdoor finned heat exchangers 105 and 108. By adjusting the outdoor heat exchange fan 111, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 101 through the water pump 102 and then sends the pressurized water into the spray components 103 and 104, to cool the outdoor heat exchangers 105 and 108, respectively. The cooled refrigerant enters the main refrigerant liquid pipeline 109 through the outdoor heat exchanger liquid outlet pipeline. After being regulated and pressurized by the refrigerant circulating pump 117, the cooled refrigerant is sent through the refrigerant circulating pump liquid outlet pipe 118 to the electronic expansion valves 119, 123, 127, and 131 for throttling. The throttled refrigerant enters the indoor heat exchangers 121, 125, 129 and 133 for evaporation through the throttled refrigerant distribution pipeline again, and then the evaporated refrigerant enters the main return air pipeline 135 again through the return air pipelines 122, 126, 130, and 134. In this way, a complete refrigeration cycle is formed. The outdoor heat exchange fan 111 and the indoor heat exchange fans 120, 124, 128 and 132 may be adjusted respectively according to the indoor load of the data center computer room.

Further, driven by the indoor heat exchange fans 220, 224, 228 and 232, the heat passes through the indoor heat exchangers 221, 225, 229 and 233, and exchanges heat with the refrigerant evaporated after throttling, then flows out of the indoor heat exchange channels of the indoor heat exchangers 221, 225, 229 and 233, and then is sent to the computer room through the indoor air supply channel to cool the server clusters 01, 02, 03, and 04. The refrigerant gas evaporated in the indoor heat exchangers flows through the indoor heat exchanger return air pipelines 222, 226, 230 and 234, flows into the magnetic levitation compressor 213 through the main return air pipeline 235, then enters the first one-way valve 212 after compression, then enters the outdoor condenser air inlet pipeline 210, then passes through the outdoor heat exchanger air inlet pipelines 206 and 207 respectively, and then enters the outdoor finned heat exchangers 205 and 208. By adjusting the outdoor heat exchange fan 211, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 201 through the water pump 202 and then sends the pressurized water into the spray components 203 and 204, to cool the outdoor heat exchangers 205 and 208, respectively. The cooled refrigerant enters the main refrigerant liquid pipeline 209 through the outdoor heat exchanger liquid outlet pipeline. After being regulated and pressurized by the refrigerant circulating pump 217, the cooled refrigerant is sent through the refrigerant circulating pump liquid outlet pipe 218 to the electronic expansion valves 219, 223, 227, and 231 for throttling. The throttled refrigerant enters the indoor heat exchangers 221, 225, 229 and 233 for evaporation through the throttled refrigerant distribution pipeline again, and then the evaporated refrigerant enters the main return air pipeline 235 again through the return air pipelines 222, 226, 230, and 234. In this way, a complete refrigeration cycle is formed. The outdoor heat exchange fan 211 and the indoor heat exchange fans 220, 224, 228 and 232 may be adjusted respectively according to indoor load of the data center computer room.

Further, driven by the indoor heat exchange fans 320, 324, 328 and 332, the heat passes through the indoor heat exchangers 321, 325, 329 and 333, and exchanges heat with the refrigerant evaporated after throttling, then flows out of the indoor heat exchange channels of the indoor heat exchangers 321, 325, 329 and 333, and then is sent to the computer room through the indoor air supply channel to cool the server clusters 01, 02, 03, and 04. The refrigerant gas evaporated in the indoor heat exchangers flows through the indoor heat exchanger return air pipelines 322, 326, 330 and 334, flows into the magnetic levitation compressor 313 through the main return air pipeline 335, then enters the first one-way valve 312 after compression, then enters the outdoor condenser air inlet pipeline 310, then passes through the outdoor heat exchanger air inlet pipelines 306 and 307 respectively, and then enters the outdoor finned heat exchangers 305 and 308. By adjusting the outdoor heat exchange fan 311, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 301 through the water pump 302 and then sends the pressurized water into the spray components 303 and 304, to cool the outdoor heat exchangers 305 and 308, respectively. The cooled refrigerant enters the main refrigerant liquid pipeline 309 through the outdoor heat exchanger liquid outlet pipeline. After being regulated and pressurized by the refrigerant circulating pump 317, the cooled refrigerant is sent through the refrigerant circulating pump liquid outlet pipe 318 to the electronic expansion valves 319, 323, 327, and 331 for throttling. The throttled refrigerant enters the indoor heat exchangers 321, 325, 329 and 333 for evaporation through the throttled refrigerant distribution pipeline again, and then the evaporated refrigerant enters the main return air pipeline 335 again through the return air pipelines 322, 326, 330, and 334. In this way, a complete refrigeration cycle is formed. The outdoor heat exchange fan 311 and the indoor heat exchange fans 320, 324, 328 and 332 may be adjusted respectively according to the indoor load of the data center computer room, to obtain the stable indoor target temperature, thereby reducing the power consumption of the outdoor and indoor heat exchange fans. The magnetic levitation centrifugal compressor only needs to work for a small amount of time in a high-temperature environment, thus saving energy consumption.

In one embodiment, reference is made to FIG. 1. The number of the servers in the server clusters 01, 02, 03 and 04 from the data center computer room increases, and the heat generated by the servers also increases. Driven by the indoor heat exchange fans 120, 124, 128 and 132, the heat passes through the indoor heat exchangers 121, 125, 129 and 133, and exchanges heat with the refrigerant evaporated after throttling, then flows out of the indoor heat exchange channels of the indoor heat exchangers 121, 125, 129 and 133, and then is sent to the computer room through the indoor air supply channel to cool the server clusters 01, 02, 03, and 04. The refrigerant gas evaporated in the indoor heat exchangers flows through the indoor heat exchanger return air pipelines 122, 126, 130 and 134, flows into the air inlet pipeline 116 and the second one-way valve 115 through the main return air pipeline 135, then flows into the outdoor condenser air inlet pipeline 110 through the pipeline 114, then passes through the outdoor heat exchanger air inlet pipelines 106 and 107 respectively, and enters the outdoor finned heat exchangers 105 and 108. By adjusting the outdoor heat exchange fan 111, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 101 through the water pump 102 and then sends the pressurized water into the spray components 103 and 104, to cool the outdoor heat exchangers 105 and 108, respectively. The cooled refrigerant enters the main refrigerant liquid pipeline 109 through the outdoor heat exchanger liquid outlet pipeline. After being regulated and pressurized by the refrigerant circulating pump 117, the cooled refrigerant is sent through the refrigerant circulating pump liquid outlet pipe 118 to the electronic expansion valves 119, 123, 127, and 131 for throttling. The throttled refrigerant enters the indoor heat exchangers 121, 125, 129 and 133 for evaporation through the throttled refrigerant distribution pipeline again, and then the evaporated refrigerant enters the main return air pipeline 135 again through the return air pipelines 122, 126, 130, and 134. In this way, a complete refrigeration cycle is formed. The outdoor heat exchange fan 111 and the indoor heat exchange fans 120, 124, 128 and 132 may be adjusted respectively according to indoor load of the data center computer room.

Further, driven by the indoor heat exchange fans 220, 224, 228 and 232, the heat passes through the indoor heat exchangers 221, 225, 229 and 233, and exchanges heat with the refrigerant evaporated after throttling, then flows out of the indoor heat exchange channels of the indoor heat exchangers 221, 225, 229 and 233, and then is sent to the computer room through the indoor air supply channel to cool the server clusters 01, 02, 03, and 04. The refrigerant gas evaporated in the indoor heat exchangers flows through the indoor heat exchanger return air pipelines 222, 226, 230 and 234, flows into the air inlet pipeline 216 and the second one-way valve 215 through the main return air pipeline 235, then flows into the outdoor condenser air inlet pipeline 210 through the pipeline 214, then passes through the outdoor heat exchanger air inlet pipelines 206 and 207 respectively, and enters the outdoor finned heat exchangers 205 and 208. By adjusting the outdoor heat exchange fan 211, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 201 through the water pump 202 and then sends the pressurized water into the spray components 203 and 204, to cool the outdoor heat exchangers 205 and 208, respectively. The cooled refrigerant enters the main refrigerant liquid pipeline 209 through the outdoor heat exchanger liquid outlet pipeline. After being regulated and pressurized by the refrigerant circulating pump 217, the cooled refrigerant is sent through the refrigerant circulating pump liquid outlet pipe 218 to the electronic expansion valves 219, 223, 227, and 231 for throttling. The throttled refrigerant enters the indoor heat exchangers 221, 225, 229 and 233 for evaporation through the throttled refrigerant distribution pipeline again, and then the evaporated refrigerant enters the main return air pipeline 235 again through the return air pipelines 222, 226, 230, and 234. In this way, a complete refrigeration cycle is formed. The outdoor heat exchange fan 211 and the indoor heat exchange fans 220, 224, 228 and 232 may be adjusted respectively according to the indoor load of the data center computer room.

Further, driven by the indoor heat exchange fans 320, 324, 328 and 332, the heat passes through the indoor heat exchangers 321, 325, 329 and 333, and exchanges heat with the refrigerant evaporated after throttling, then flows out of the indoor heat exchange channels of the indoor heat exchangers 321, 325, 329 and 333, and then is sent to the computer room through the indoor air supply channel to cool the server clusters 01, 02, 03, and 04. The refrigerant gas evaporated in the indoor heat exchangers flows through the indoor heat exchanger return air pipelines 322, 326, 330 and 334, flows into the air inlet pipeline 316 and the second one-way valve 315 through the main return air pipeline 335, then flows into the outdoor condenser air inlet pipeline 310 through the pipeline 314, then passes through the outdoor heat exchanger air inlet pipelines 306 and 307 respectively, and enters the outdoor finned heat exchangers 305 and 308. By adjusting the outdoor heat exchange fan 311, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 301 through the water pump 302 and then sends the pressurized water into the spray components 303 and 304, to cool the outdoor heat exchangers 305 and 308, respectively. The cooled refrigerant enters the main refrigerant liquid pipeline 309 through the outdoor heat exchanger liquid outlet pipeline. After being regulated and pressurized by the refrigerant circulating pump 317, the cooled refrigerant is sent through the refrigerant circulating pump liquid outlet pipe 318 to the electronic expansion valves 319, 323, 327, and 331 for throttling. The throttled refrigerant enters the indoor heat exchangers 321, 325, 329 and 333 for evaporation through the throttled refrigerant distribution pipeline again, and then the evaporated refrigerant enters the main return air pipeline 335 again through the return air pipelines 322, 326, 330, and 334. In this way, a complete refrigeration cycle is formed. The outdoor heat exchange fan 311 and the indoor heat exchange fans 320, 324, 328 and 332 may be adjusted respectively according to indoor load of the data center computer room.

Further, driven by the indoor heat exchange fans 420, 424, 428 and 432, the heat passes through the indoor heat exchangers 421, 425, 429 and 433, and exchanges heat with the refrigerant evaporated after throttling, then flows out of the indoor heat exchange channels of the indoor heat exchangers 421, 425, 429 and 433, and then is sent to the computer room through the indoor air supply channel to cool the server clusters 01, 02, 03, and 04. The refrigerant gas evaporated in the indoor heat exchangers flows through the indoor heat exchanger return air pipelines 422, 426, 430 and 434, flows into the air inlet pipeline 416 and the second one-way valve 415 through the main return air pipeline 435, then flows into the outdoor condenser air inlet pipeline 410 through the pipeline 414, then passes through the outdoor heat exchanger air inlet pipelines 406 and 407 respectively, and enters the outdoor finned heat exchangers 405 and 408. By adjusting the outdoor heat exchange fan 411, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 401 through the water pump 402 and then sends the pressurized water into the spray components 403 and 404, to cool the outdoor heat exchangers 405 and 408, respectively. The cooled refrigerant enters the main refrigerant liquid pipeline 409 through the outdoor heat exchanger liquid outlet pipeline. After being regulated and pressurized by the refrigerant circulating pump 417, the cooled refrigerant is sent through the refrigerant circulating pump liquid outlet pipe 418 to the electronic expansion valves 419, 423, 427, and 431 for throttling. The throttled refrigerant enters the indoor heat exchangers 421, 425, 429 and 433 for evaporation through the throttled refrigerant distribution pipeline again, and then the evaporated refrigerant enters the main return air pipeline 435 again through the return air pipelines 422, 426, 430, and 434. In this way, a complete refrigeration cycle is formed. The outdoor heat exchange fan 411 and the indoor heat exchange fans 420, 424, 428 and 432 may be adjusted respectively according to the indoor load of the data center computer room, to obtain the stable indoor target temperature, thereby reducing the power consumption of the outdoor and indoor heat exchange fans. The required indoor target temperature can be obtained by means of natural cooling without starting the compressor, thus saving energy consumption.

Further, the number of the servers in the server clusters 01, 02, 03 and 04 from the data center computer room increases, and heat generated by the servers also increases. Driven by the indoor heat exchange fans 120, 124, 128 and 132, the heat passes through the indoor heat exchangers 121, 125, 129 and 133, and exchanges heat with the refrigerant evaporated after throttling, then flows out of the indoor heat exchange channels of the indoor heat exchangers 121, 125, 129 and 133, and then is sent to the computer room through the indoor air supply channel to cool the server clusters 01, 02, 03, and 04. The refrigerant gas evaporated in the indoor heat exchangers flows through the indoor heat exchanger return air pipelines 122, 126, 130 and 134, flows into the magnetic levitation compressor 113 through the main return air pipeline 135, then enters the first one-way valve 112 after compression, then enters the outdoor condenser air inlet pipeline 110, then passes through the outdoor heat exchanger air inlet pipelines 106 and 107 respectively, and then enters the outdoor finned heat exchangers 105 and 108. By adjusting the outdoor heat exchange fan 111, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 101 through the water pump 102 and then sends the pressurized water into the spray components 103 and 104, to cool the outdoor heat exchangers 105 and 108, respectively. The cooled refrigerant enters the main refrigerant liquid pipeline 109 through the outdoor heat exchanger liquid outlet pipeline. After being regulated and pressurized by the refrigerant circulating pump 117, the cooled refrigerant is sent through the refrigerant circulating pump liquid outlet pipe 118 to the electronic expansion valves 119, 123, 127, and 131 for throttling. The throttled refrigerant enters the indoor heat exchangers 121, 125, 129 and 133 for evaporation through the throttled refrigerant distribution pipeline again, and then the evaporated refrigerant enters the main return air pipeline 135 again through the return air pipelines 122, 126, 130, and 134. In this way, a complete refrigeration cycle is formed. The outdoor heat exchange fan 111 and the indoor heat exchange fans 120, 124, 128 and 132 may be adjusted respectively according to the indoor load of the data center computer room.

Further, driven by the indoor heat exchange fans 220, 224, 228 and 232, the heat passes through the indoor heat exchangers 221, 225, 229 and 233, and exchanges heat with the refrigerant evaporated after throttling, then flows out of the indoor heat exchange channels of the indoor heat exchangers 221, 225, 229 and 233, and then is sent to the computer room through the indoor air supply channel to cool the server clusters 01, 02, 03, and 04. The refrigerant gas evaporated in the indoor heat exchangers flows through the indoor heat exchanger return air pipelines 222, 226, 230 and 234, flows into the magnetic levitation compressor 213 through the main return air pipeline 235, then enters the first one-way valve 212 after compression, then enters the outdoor condenser air inlet pipeline 210, then passes through the outdoor heat exchanger air inlet pipelines 206 and 207 respectively, and then enters the outdoor finned heat exchangers 205 and 208. By adjusting the outdoor heat exchange fan 211, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 201 through the water pump 202 and then sends the pressurized water into the spray components 203 and 204, to cool the outdoor heat exchangers 205 and 208, respectively. The cooled refrigerant enters the main refrigerant liquid pipeline 209 through the outdoor heat exchanger liquid outlet pipeline. After being regulated and pressurized by the refrigerant circulating pump 217, the cooled refrigerant is sent through the refrigerant circulating pump liquid outlet pipe 218 to the electronic expansion valves 219, 223, 227, and 231 for throttling. The throttled refrigerant enters the indoor heat exchangers 221, 225, 229 and 233 for evaporation through the throttled refrigerant distribution pipeline again, and then the evaporated refrigerant enters the main return air pipeline 235 again through the return air pipelines 222, 226, 230, and 234. In this way, a complete refrigeration cycle is formed. The outdoor heat exchange fan 211 and the indoor heat exchange fans 220, 224, 228 and 232 may be adjusted respectively according to indoor load of the data center computer room.

Further, driven by the indoor heat exchange fans 320, 324, 328 and 332, the heat passes through the indoor heat exchangers 321, 325, 329 and 333, and exchanges heat with the refrigerant evaporated after throttling, then flows out of the indoor heat exchange channels of the indoor heat exchangers 321, 325, 329 and 333, and then is sent to the computer room through the indoor air supply channel to cool the server clusters 01, 02, 03, and 04. The refrigerant gas evaporated in the indoor heat exchangers flows through the indoor heat exchanger return air pipelines 322, 326, 330 and 334, flows into the magnetic levitation compressor 313 through the main return air pipeline 335, then enters the first one-way valve 312 after compression, then enters the outdoor condenser air inlet pipeline 310, then passes through the outdoor heat exchanger air inlet pipelines 306 and 307 respectively, and then enters the outdoor finned heat exchangers 305 and 308. By adjusting the outdoor heat exchange fan 311, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 301 through the water pump 302 and then sends the pressurized water into the spray components 303 and 304, to cool the outdoor heat exchangers 305 and 308, respectively. The cooled refrigerant enters the main refrigerant liquid pipeline 309 through the outdoor heat exchanger liquid outlet pipeline. After being regulated and pressurized by the refrigerant circulating pump 317, the cooled refrigerant is sent through the refrigerant circulating pump liquid outlet pipe 318 to the electronic expansion valves 319, 323, 327, and 331 for throttling. The throttled refrigerant enters the indoor heat exchangers 321, 325, 329 and 333 for evaporation through the throttled refrigerant distribution pipeline again, and then the evaporated refrigerant enters the main return air pipeline 335 again through the return air pipelines 322, 326, 330, and 334. In this way, a complete refrigeration cycle is formed. The outdoor heat exchange fan 311 and the indoor heat exchange fans 320, 324, 328 and 332 may be adjusted respectively according to indoor load of the data center computer room.

Further, driven by the indoor heat exchange fans 420, 424, 428 and 432, the heat passes through the indoor heat exchangers 421, 425, 429 and 433, and exchanges heat with the refrigerant evaporated after throttling, then flows out of the indoor heat exchange channels of the indoor heat exchangers 421, 425, 429 and 433, and then is sent to the computer room through the indoor air supply channel to cool the server clusters 01, 02, 03, and 04. The refrigerant gas evaporated in the indoor heat exchangers flows through the indoor heat exchanger return air pipelines 422, 426, 430 and 434, flows into the magnetic levitation compressor 413 through the main return air pipeline 435, then enters the first one-way valve 412 after compression, then enters the outdoor condenser air inlet pipeline 410, then passes through the outdoor heat exchanger air inlet pipelines 406 and 407 respectively, and then enters the outdoor finned heat exchangers 405 and 408. By adjusting the outdoor heat exchange fan 411, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 401 through the water pump 402 and then sends the pressurized water into the spray components 403 and 404, to cool the outdoor heat exchangers 405 and 408, respectively. The cooled refrigerant enters the main refrigerant liquid pipeline 409 through the outdoor heat exchanger liquid outlet pipeline. After being regulated and pressurized by the refrigerant circulating pump 417, the cooled refrigerant is sent through the refrigerant circulating pump liquid outlet pipe 418 to the electronic expansion valves 419, 423, 427, and 431 for throttling. The throttled refrigerant enters the indoor heat exchangers 421, 425, 429 and 433 for evaporation through the throttled refrigerant distribution pipeline again, and then the evaporated refrigerant enters the main return air pipeline 435 again through the return air pipelines 422, 426, 430, and 434. In this way, a complete refrigeration cycle is formed. The outdoor heat exchange fan 411 and the indoor heat exchange fans 420, 424, 428 and 432 may be adjusted respectively according to the indoor load of the data center computer room, to obtain the stable indoor target temperature, thereby reducing the power consumption of the outdoor and indoor heat exchange fans. The magnetic levitation centrifugal compressor only needs to work for a small amount of time in a high-temperature environment, thus saving energy consumption.

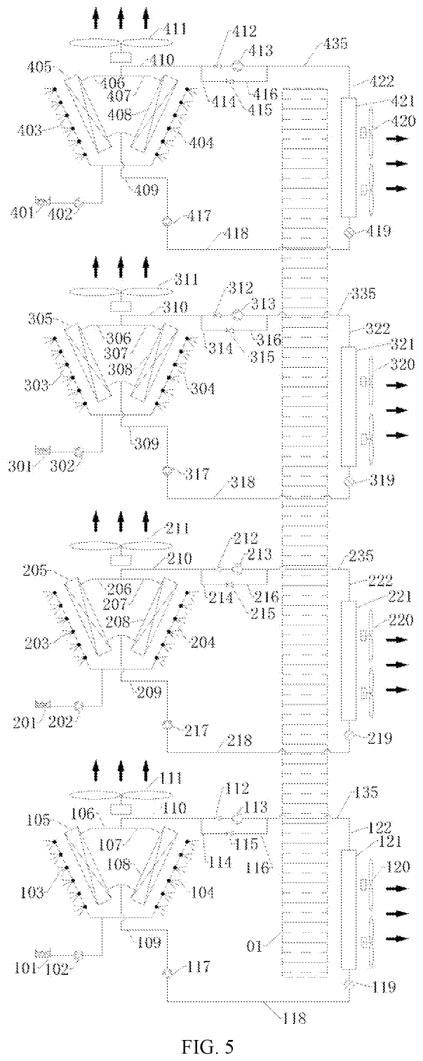

In one embodiment, reference is made to FIG. 5. A server in the server cluster 01 from the data center computer room is operating, and heat generated is also reduced. Driven by the indoor heat exchange fan 120, the heat passes through the indoor heat exchanger 121, and exchanges heat with the refrigerant evaporated after throttling, then flows out of the indoor heat exchange channel of the indoor heat exchanger 121, and then is sent to the computer room through the indoor air supply channel to cool the server cluster 01. The refrigerant gas evaporated in the indoor heat exchangers flows through the indoor heat exchanger return air pipeline 122, flows into the air inlet pipeline 116 and the second one-way valve 115 through the main return air pipeline 135, then flows into the outdoor condenser air inlet pipeline 110 through the pipeline 114, then passes through the outdoor heat exchanger air inlet pipelines 106 and 107 respectively, and enters the outdoor finned heat exchangers 105 and 108. By adjusting the outdoor heat exchange fan 111, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 101 through the water pump 102 and then sends the pressurized water into the spray components 103 and 104, to cool the outdoor heat exchangers 105 and 108, respectively. The cooled refrigerant enters the main refrigerant liquid pipeline 109 through the outdoor heat exchanger liquid outlet pipeline. After being regulated and pressurized by the refrigerant circulating pump 117, the cooled refrigerant is sent through the refrigerant circulating pump liquid outlet pipe 118 to the electronic expansion valve 119 for throttling. The throttled refrigerant enters the indoor heat exchanger 121 for evaporation through the throttled refrigerant distribution pipeline again, and then the evaporated refrigerant enters the main return air pipeline 135 again through the return air pipeline 122. In this way, a complete refrigeration cycle is formed. The outdoor heat exchange fan 111 and the indoor heat exchange fan 120 may be adjusted respectively according to the indoor load of the data center computer room.

Further, driven by the indoor heat exchange fan 220, the heat passes through the indoor heat exchanger 221, and exchanges heat with the refrigerant evaporated after throttling, then flows out of the indoor heat exchange channel of the indoor heat exchanger 221, and then is sent to the computer room through the indoor air supply channel to cool the server cluster 01. The refrigerant gas evaporated in the indoor heat exchangers flows through the indoor heat exchanger return air pipeline 222, flows into the air inlet pipeline 216 and the second one-way valve 215 through the main return air pipeline 235, then flows into the outdoor condenser air inlet pipeline 210 through the pipeline 214, then passes through the outdoor heat exchanger air inlet pipelines 206 and 207 respectively, and enters the outdoor finned heat exchangers 205 and 208. By adjusting the outdoor heat exchange fan 211, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 201 through the water pump 202 and then sends the pressurized water into the spray components 203 and 204, to cool the outdoor heat exchangers 205 and 208, respectively. The cooled refrigerant enters the main refrigerant liquid pipeline 209 through the outdoor heat exchanger liquid outlet pipeline. After being regulated and pressurized by the refrigerant circulating pump 217, the cooled refrigerant is sent through the refrigerant circulating pump liquid outlet pipe 218 to the electronic expansion valve 219 for throttling. The throttled refrigerant enters the indoor heat exchanger 221 for evaporation through the throttled refrigerant distribution pipeline again, and then the evaporated refrigerant enters the main return air pipeline 235 again through the return air pipeline 222. In this way, a complete refrigeration cycle is formed. The outdoor heat exchange fan 211 and the indoor heat exchange fan 220 may be adjusted respectively according to the indoor load of the data center computer room.

Further, driven by the indoor heat exchange fan 320, the heat passes through the indoor heat exchanger 321, then exchanges heat with the refrigerant evaporated after throttling, then flows out of the indoor heat exchange channel of the indoor heat exchanger 321, and then is sent to the computer room through the indoor air supply channel to cool the server cluster 01. The refrigerant gas evaporated in the indoor heat exchangers flows through the indoor heat exchanger return air pipeline 322, flows into the air inlet pipeline 316 and the second one-way valve 315 through the main return air pipeline 335, then flows into the outdoor condenser air inlet pipeline 310 through the pipeline 314, then passes through the outdoor heat exchanger air inlet pipelines 306 and 307 respectively, and enters the outdoor finned heat exchangers 305 and 308. By adjusting the outdoor heat exchange fan 311, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 301 through the water pump 302 and then sends the pressurized water into the spray components 303 and 304, to cool the outdoor heat exchangers 305 and 308, respectively. The cooled refrigerant enters the main refrigerant liquid pipeline 309 through the outdoor heat exchanger liquid outlet pipeline. After being regulated and pressurized by the refrigerant circulating pump 317, the cooled refrigerant is sent through the refrigerant circulating pump liquid outlet pipe 318 to the electronic expansion valve 319 for throttling. The throttled refrigerant enters the indoor heat exchanger 321 for evaporation through the throttled refrigerant distribution pipeline again, and then the evaporated refrigerant enters the main return air pipeline 335 again through the return air pipeline 322. In this way, a complete refrigeration cycle is formed. The outdoor heat exchange fan 311 and the indoor heat exchange fans 320, 324, 328 and 332 may be adjusted respectively according to indoor load of the data center computer room.

Further, driven by the indoor heat exchange fan 420, the heat passes through the indoor heat exchanger 421, then exchanges heat with the refrigerant evaporated after throttling, then flows out of the indoor heat exchange channel of the indoor heat exchanger 421, and then is sent to the computer room through the indoor air supply channel to cool the server cluster 01. The refrigerant gas evaporated in the indoor heat exchangers flows through the indoor heat exchanger return air pipeline 422, flows into the air inlet pipeline 416 and the second one-way valve 415 through the main return air pipeline 435, then flows into the outdoor condenser air inlet pipeline 410 through the pipeline 414, then passes through the outdoor heat exchanger air inlet pipelines 406 and 407 respectively, and enters the outdoor finned heat exchangers 405 and 408. By adjusting the outdoor heat exchange fan 411, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 401 through the water pump 402 and then sends the pressurized water into the spray components 403 and 404, to cool the outdoor heat exchangers 405 and 408, respectively. The cooled refrigerant enters the main refrigerant liquid pipeline 409 through the outdoor heat exchanger liquid outlet pipeline. After being regulated and pressurized by the refrigerant circulating pump 417, the cooled refrigerant is sent through the refrigerant circulating pump liquid outlet pipe 418 to the electronic expansion valve 419 for throttling. The throttled refrigerant enters the indoor heat exchanger 421 for evaporation through the throttled refrigerant distribution pipeline again, and then the evaporated refrigerant enters the main return air pipeline 435 again through the return air pipeline 422. In this way, a complete refrigeration cycle is formed. The outdoor heat exchange fan 411 and the indoor heat exchange fan 420 may be adjusted respectively according to the indoor load of the data center computer room, to obtain the stable indoor target temperature, thereby reducing the power consumption of the outdoor and indoor heat exchange fans. The required indoor target temperature can be obtained by means of natural cooling without starting the compressor, thus saving energy consumption.

Further, the number of the servers in the server cluster 01 from the data center computer room increases, and heat generated by the servers also increases. Driven by the indoor heat exchange fan 120, the heat passes through the indoor heat exchanger 121, and exchanges heat with the refrigerant evaporated after throttling, then flows out of the indoor heat exchange channel of the indoor heat exchanger 121, and then is sent to the computer room through the indoor air supply channel to cool the server cluster 01. The refrigerant gas evaporated in the indoor heat exchangers flows through the indoor heat exchanger return air pipeline 122, flows into the magnetic levitation compressor 113 through the main return air pipeline 135, then enters the first one-way valve 112 after compression, then enters the outdoor condenser air inlet pipeline 110, then passes through the outdoor heat exchanger air inlet pipelines 106 and 107 respectively, and then enters the outdoor finned heat exchangers 105 and 108. By adjusting the outdoor heat exchange fan 111, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 101 through the water pump 102 and then sends the pressurized water into the spray components 103 and 104, to cool the outdoor heat exchangers 105 and 108, respectively. The cooled refrigerant enters the main refrigerant liquid pipeline 109 through the outdoor heat exchanger liquid outlet pipeline. After being regulated and pressurized by the refrigerant circulating pump 117, the cooled refrigerant is sent through the refrigerant circulating pump liquid outlet pipe 118 to the electronic expansion valve 119 for throttling. The throttled refrigerant enters the indoor heat exchanger 121 for evaporation through the throttled refrigerant distribution pipeline again, and then the evaporated refrigerant enters the main return air pipeline 135 again through the return air pipeline 122. In this way, a complete refrigeration cycle is formed. The outdoor heat exchange fan 111 and the indoor heat exchange fan 120 may be adjusted respectively according to the indoor load of the data center computer room.

Further, driven by the indoor heat exchange fan 220, the heat passes through the indoor heat exchanger 221, then exchanges heat with the refrigerant evaporated after throttling, then flows out of the indoor heat exchange channel of the indoor heat exchanger 221, and then is sent to the computer room through the indoor air supply channel to cool the server cluster 01. The refrigerant gas evaporated in the indoor heat exchangers flows through the indoor heat exchanger return air pipeline 222, flows into the magnetic levitation compressor 213 through the main return air pipeline 235, then enters the first one-way valve 212 after compression, then enters the outdoor condenser air inlet pipeline 210, then passes through the outdoor heat exchanger air inlet pipelines 206 and 207 respectively, and then enters the outdoor finned heat exchangers 205 and 208. By adjusting the outdoor heat exchange fan 211, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 201 through the water pump 202 and then sends the pressurized water into the spray components 203 and 204, to cool the outdoor heat exchangers 205 and 208, respectively. The cooled refrigerant enters the main refrigerant liquid pipeline 209 through the outdoor heat exchanger liquid outlet pipeline. After being regulated and pressurized by the refrigerant circulating pump 217, the cooled refrigerant is sent through the refrigerant circulating pump liquid outlet pipe 218 to the electronic expansion valve 219 for throttling. The throttled refrigerant enters the indoor heat exchanger 221 for evaporation through the throttled refrigerant distribution pipeline again, and then the evaporated refrigerant enters the main return air pipeline 235 again through the return air pipeline 222. In this way, a complete refrigeration cycle is formed. The outdoor heat exchange fan 211 and the indoor heat exchange fan 220 may be adjusted respectively according to the indoor load of the data center computer room.

Further, driven by the indoor heat exchange fan 320, the heat passes through the indoor heat exchanger 321, then exchanges heat with the refrigerant evaporated after throttling, then flows out of the indoor heat exchange channel of the indoor heat exchanger 321, and then is sent to the computer room through the indoor air supply channel to cool the server cluster 01. The refrigerant gas evaporated in the indoor heat exchangers flows through the indoor heat exchanger return air pipeline 322, flows into the magnetic levitation compressor 313 through the main return air pipeline 335, then enters the first one-way valve 312 after compression, then enters the outdoor condenser air inlet pipeline 310, then passes through the outdoor heat exchanger air inlet pipelines 306 and 307 respectively, and then enters the outdoor finned heat exchangers 305 and 308. By adjusting the outdoor heat exchange fan 311, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 301 through the water pump 302 and then sends the pressurized water into the spray components 303 and 304, to cool the outdoor heat exchangers 305 and 308, respectively. The cooled refrigerant enters the main refrigerant liquid pipeline 309 through the outdoor heat exchanger liquid outlet pipeline. After being regulated and pressurized by the refrigerant circulating pump 317, the cooled refrigerant is sent through the refrigerant circulating pump liquid outlet pipe 318 to the electronic expansion valve 319 for throttling. The throttled refrigerant enters the indoor heat exchanger 321 for evaporation through the throttled refrigerant distribution pipeline again, and then the evaporated refrigerant enters the main return air pipeline 335 again through the return air pipeline 322. In this way, a complete refrigeration cycle is formed. The outdoor heat exchange fan 311 and the indoor heat exchange fan 320 may be adjusted respectively according to the indoor load of the data center computer room.

Further, driven by the indoor heat exchange fan 420, the heat passes through the indoor heat exchanger 421, then exchanges heat with the refrigerant evaporated after throttling, then flows out of the indoor heat exchange channel of the indoor heat exchanger 421, and then is sent to the computer room through the indoor air supply channel to cool the server cluster 01. The refrigerant gas evaporated in the indoor heat exchangers flows through the indoor heat exchanger return air pipeline 422, flows into the magnetic levitation compressor 413 through the main return air pipeline 435, then enters the first one-way valve 412 after compression, then enters the outdoor condenser air inlet pipeline 410, then passes through the outdoor heat exchanger air inlet pipelines 406 and 407 respectively, and then enters the outdoor finned heat exchangers 405 and 408. By adjusting the outdoor heat exchange fan 411, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 401 through the water pump 402 and then sends the pressurized water into the spray components 403 and 404, to cool the outdoor heat exchangers 405 and 408, respectively. The cooled refrigerant enters the main refrigerant liquid pipeline 409 through the outdoor heat exchanger liquid outlet pipeline. After being regulated and pressurized by the refrigerant circulating pump 417, the cooled refrigerant is sent through the refrigerant circulating pump liquid outlet pipe 418 to the electronic expansion valve 419 for throttling. The throttled refrigerant enters the indoor heat exchanger 421 for evaporation through the throttled refrigerant distribution pipeline again, and then the evaporated refrigerant enters the main return air pipeline 435 again through the return air pipeline 422. In this way, a complete refrigeration cycle is formed. The outdoor heat exchange fan 411 and the indoor heat exchange fan 420 may be adjusted respectively according to the indoor load of the data center computer room, to obtain the stable indoor target temperature, thereby reducing the power consumption of the outdoor and indoor heat exchange fans. The magnetic levitation centrifugal compressor only needs to work for a small amount of time in a high-temperature environment, thus saving energy consumption.

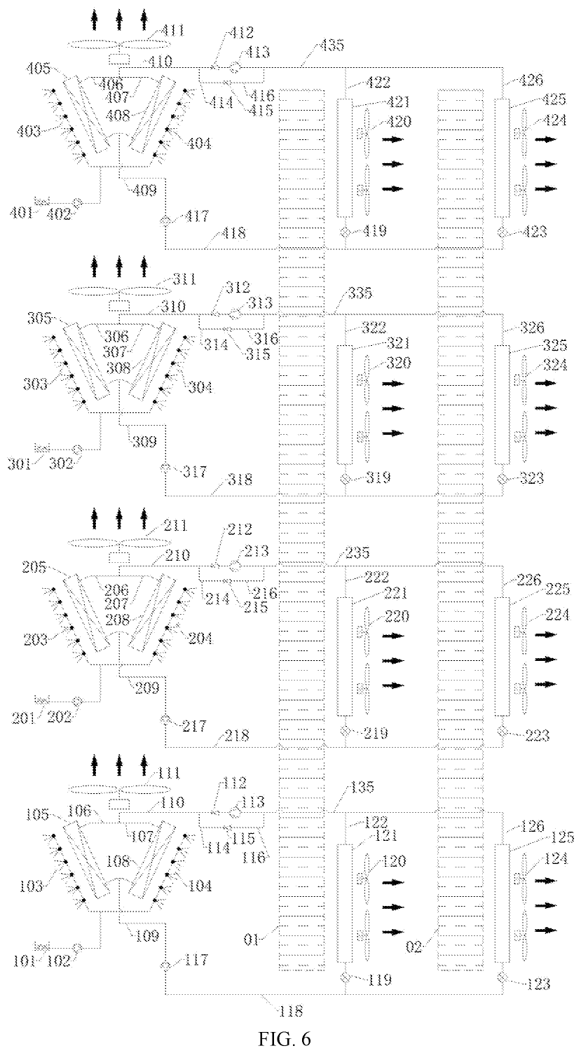

In one embodiment, reference is made to FIG. 6. The number of the servers in the server clusters 01 and 02 from the data center computer room decreases, and heat generated by the servers also decreases. Driven by the indoor heat exchange fans 120 and 124, the heat passes through the indoor heat exchangers 121 and 125, and exchanges heat with the refrigerant evaporated after throttling, then flows out of the indoor heat exchange channels of the indoor heat exchangers 121 and 125, and then is sent to the computer room through the indoor air supply channel to cool the server clusters 01 and 02. The refrigerant gas evaporated in the indoor heat exchangers flows through the indoor heat exchanger return air pipelines 122 and 126, flows into the air inlet pipeline 116 and the second one-way valve 115 through the main return air pipeline 135, then flows into the outdoor condenser air inlet pipeline 110 through the pipeline 114, then passes through the outdoor heat exchanger air inlet pipelines 106 and 107 respectively, and enters the outdoor finned heat exchangers 105 and 108. By adjusting the outdoor heat exchange fan 111, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 101 through the water pump 102 and then sends the pressurized water into the spray components 103 and 104, to cool the outdoor heat exchangers 105 and 108, respectively. The cooled refrigerant enters the main refrigerant liquid pipeline 109 through the outdoor heat exchanger liquid outlet pipeline. After being regulated and pressurized by the refrigerant circulating pump 117, the cooled refrigerant is sent through the refrigerant circulating pump liquid outlet pipe 118 to the electronic expansion valves 119 and 123 for throttling. The throttled refrigerant enters the indoor heat exchangers 121 and 125 for evaporation through the throttled refrigerant distribution pipeline again, and then the evaporated refrigerant enters the main return air pipeline 135 again through the return air pipelines 122 and 126. In this way, a complete refrigeration cycle is formed. The outdoor heat exchange fan 111 and the indoor heat exchange fans 120 and 124 may be adjusted respectively according to the indoor load of the data center computer room.

Further, driven by the indoor heat exchange fans 220 and 224, the heat passes through the indoor heat exchangers 221 and 225, then exchanges heat with the refrigerant evaporated after throttling, then flows out of the indoor heat exchange channels of the indoor heat exchangers 221 and 225, and then is sent to the computer room through the indoor air supply channel to cool the server clusters 01 and 02. The refrigerant gas evaporated in the indoor heat exchangers flows through the indoor heat exchanger return air pipelines 222 and 226, flows into the air inlet pipeline 216 and the second one-way valve 215 through the main return air pipeline 235, then flows into the outdoor condenser air inlet pipeline 210 through the pipeline 214, then passes through the outdoor heat exchanger air inlet pipelines 206 and 207 respectively, and enters the outdoor finned heat exchangers 205 and 208. By adjusting the outdoor heat exchange fan 211, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 201 through the water pump 202 and then sends the pressurized water into the spray components 203 and 204, to cool the outdoor heat exchangers 205 and 208, respectively. The cooled refrigerant enters the main refrigerant liquid pipeline 209 through the outdoor heat exchanger liquid outlet pipeline. After being regulated and pressurized by the refrigerant circulating pump 217, the cooled refrigerant is sent through the refrigerant circulating pump liquid outlet pipe 218 to the electronic expansion valves 219 and 223 for throttling. The throttled refrigerant enters the indoor heat exchangers 221 and 225 for evaporation through the throttled refrigerant distribution pipeline again, and then the evaporated refrigerant enters the main return air pipeline 235 again through the return air pipelines 222 and 226. In this way, a complete refrigeration cycle is formed. The outdoor heat exchange fan 211 and the indoor heat exchange fans 220 and 224 may be adjusted respectively according to the indoor load of the data center computer room.

Further, driven by the indoor heat exchange fans 320 and 324, the heat passes through the indoor heat exchangers 321 and 325, then exchanges heat with the refrigerant evaporated after throttling, then flows out of the indoor heat exchange channels of the indoor heat exchangers 321 and 325, and then is sent to the computer room through the indoor air supply channel to cool the server clusters 01 and 02. The refrigerant gas evaporated in the indoor heat exchangers flows through the indoor heat exchanger return air pipelines 322 and 326, flows into the air inlet pipeline 316 and the second one-way valve 315 through the main return air pipeline 335, then flows into the outdoor condenser air inlet pipeline 310 through the pipeline 314, then passes through the outdoor heat exchanger air inlet pipelines 306 and 307 respectively, and enters the outdoor finned heat exchangers 305 and 308. By adjusting the outdoor heat exchange fan 311, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 301 through the water pump 302 and then sends the pressurized water into the spray components 303 and 304, to cool the outdoor heat exchangers 305 and 308, respectively. The cooled refrigerant enters the main refrigerant liquid pipeline 309 through the outdoor heat exchanger liquid outlet pipeline. After being regulated and pressurized by the refrigerant circulating pump 317, the cooled refrigerant is sent through the refrigerant circulating pump liquid outlet pipe 318 to the electronic expansion valves 319 and 323 for throttling. The throttled refrigerant enters the indoor heat exchangers 321 and 325 for evaporation through the throttled refrigerant distribution pipeline again, and then the evaporated refrigerant enters the main return air pipeline 335 again through the return air pipelines 322 and 326. In this way, a complete refrigeration cycle is formed. The outdoor heat exchange fan 311 and the indoor heat exchange fans 320 and 324 may be adjusted respectively according to the indoor load of the data center computer room.

Further, driven by the indoor heat exchange fans 420 and 424, the heat passes through the indoor heat exchangers 421 and 425, then exchanges heat with the refrigerant evaporated after throttling, then flows out of the indoor heat exchange channels of the indoor heat exchangers 421 and 425, and then is sent to the computer room through the indoor air supply channel to cool the server clusters 01 and 02. The refrigerant gas evaporated in the indoor heat exchangers flows through the indoor heat exchanger return air pipelines 422 and 426, flows into the air inlet pipeline 416 and the second one-way valve 415 through the main return air pipeline 435, then flows into the outdoor condenser air inlet pipeline 410 through the pipeline 414, then passes through the outdoor heat exchanger air inlet pipelines 406 and 407 respectively, and enters the outdoor finned heat exchangers 405 and 408. By adjusting the outdoor heat exchange fan 411, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 401 through the water pump 402 and then sends the pressurized water into the spray components 403 and 404, to cool the outdoor heat exchangers 405 and 408, respectively. The cooled refrigerant enters the main refrigerant liquid pipeline 409 through the outdoor heat exchanger liquid outlet pipeline. After being regulated and pressurized by the refrigerant circulating pump 417, the cooled refrigerant is sent through the refrigerant circulating pump liquid outlet pipe 418 to the electronic expansion valves 419 and 423 for throttling. The throttled refrigerant enters the indoor heat exchangers 421 and 425 for evaporation through the throttled refrigerant distribution pipeline again, and then the evaporated refrigerant enters the main return air pipeline 435 again through the return air pipelines 422 and 426. In this way, a complete refrigeration cycle is formed. The outdoor heat exchange fan 411 and the indoor heat exchange fans 420 and 424 may be adjusted respectively according to the indoor load of the data center computer room, to obtain the stable indoor target temperature, thereby reducing the power consumption of the outdoor and indoor heat exchange fans. The required indoor target temperature can be obtained by means of natural cooling without starting the compressor, thus saving energy consumption.

Further, the number of the servers in the server clusters 01 and 02 from the data center computer room increases, and heat generated by the servers also increases. Driven by the indoor heat exchange fans 120 and 124, the heat passes through the indoor heat exchangers 121 and 125, and exchanges heat with the refrigerant evaporated after throttling, then flows out of the indoor heat exchange channels of the indoor heat exchangers 121 and 125, and then is sent to the computer room through the indoor air supply channel to cool the server clusters 01 and 02. The refrigerant gas evaporated in the indoor heat exchangers flows through the indoor heat exchanger return air pipelines 122 and 126, flows into the magnetic levitation compressor 113 through the main return air pipeline 135, then enters the first one-way valve 112 after compression, then enters the outdoor condenser air inlet pipeline 110, then passes through the outdoor heat exchanger air inlet pipelines 106 and 107 respectively, and then enters the outdoor finned heat exchangers 105 and 108. By adjusting the outdoor heat exchange fan 111, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 101 through the water pump 102 and then sends the pressurized water into the spray components 103 and 104, to cool the outdoor heat exchangers 105 and 108, respectively. The cooled refrigerant enters the main refrigerant liquid pipeline 109 through the outdoor heat exchanger liquid outlet pipeline. After being regulated and pressurized by the refrigerant circulating pump 117, the cooled refrigerant is sent through the refrigerant circulating pump liquid outlet pipe 118 to the electronic expansion valves 119 and 123 for throttling. The throttled refrigerant enters the indoor heat exchangers 121 and 125 for evaporation through the throttled refrigerant distribution pipeline again, and then the evaporated refrigerant enters the main return air pipeline 135 again through the return air pipelines 122 and 126. In this way, a complete refrigeration cycle is formed. The outdoor heat exchange fan 111 and the indoor heat exchange fans 120 and 124 may be adjusted respectively according to the indoor load of the data center computer room.

Further, driven by the indoor heat exchange fans 220 and 224, the heat passes through the indoor heat exchangers 221 and 225, then exchanges heat with the refrigerant evaporated after throttling, then flows out of the indoor heat exchange channels of the indoor heat exchangers 221 and 225, and then is sent to the computer room through the indoor air supply channel to cool the server clusters 01 and 02. The refrigerant gas evaporated in the indoor heat exchangers flows through the indoor heat exchanger return air pipelines 222 and 226, flows into the magnetic levitation compressor 213 through the main return air pipeline 235, then enters the first one-way valve 212 after compression, then enters the outdoor condenser air inlet pipeline 210, then passes through the outdoor heat exchanger air inlet pipelines 206 and 207 respectively, and then enters the outdoor finned heat exchangers 205 and 208. By adjusting the outdoor heat exchange fan 211, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 201 through the water pump 202 and then sends the pressurized water into the spray components 203 and 204, to cool the outdoor heat exchangers 205 and 208, respectively. The cooled refrigerant enters the main refrigerant liquid pipeline 209 through the outdoor heat exchanger liquid outlet pipeline. After being regulated and pressurized by the refrigerant circulating pump 217, the cooled refrigerant is sent through the refrigerant circulating pump liquid outlet pipe 218 to the electronic expansion valves 219 and 223 for throttling. The throttled refrigerant enters the indoor heat exchangers 221 and 225 for evaporation through the throttled refrigerant distribution pipeline again, and then the evaporated refrigerant enters the main return air pipeline 235 again through the return air pipelines 222 and 226. In this way, a complete refrigeration cycle is formed. The outdoor heat exchange fan 211 and the indoor heat exchange fans 220 and 224 may be adjusted respectively according to the indoor load of the data center computer room.

Further, driven by the indoor heat exchange fans 320 and 324, the heat passes through the indoor heat exchangers 321 and 325, then exchanges heat with the refrigerant evaporated after throttling, then flows out of the indoor heat exchange channels of the indoor heat exchangers 321 and 325, and then is sent to the computer room through the indoor air supply channel to cool the server clusters 01 and 02. The refrigerant gas evaporated in the indoor heat exchangers flows through the indoor heat exchanger return air pipelines 322 and 326, flows into the magnetic levitation compressor 313 through the main return air pipeline 335, then enters the first one-way valve 312 after compression, then enters the outdoor condenser air inlet pipeline 310, then passes through the outdoor heat exchanger air inlet pipelines 306 and 307 respectively, and then enters the outdoor finned heat exchangers 305 and 308. By adjusting the outdoor heat exchange fan 311, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 301 through the water pump 302 and then sends the pressurized water into the spray components 303 and 304, to cool the outdoor heat exchangers 305 and 308, respectively. The cooled refrigerant enters the main refrigerant liquid pipeline 309 through the outdoor heat exchanger liquid outlet pipeline. After being regulated and pressurized by the refrigerant circulating pump 317, the cooled refrigerant is sent through the refrigerant circulating pump liquid outlet pipe 318 to the electronic expansion valves 319 and 323 for throttling. The throttled refrigerant enters the indoor heat exchangers 321 and 325 for evaporation through the throttled refrigerant distribution pipeline again, and then the evaporated refrigerant enters the main return air pipeline 335 again through the return air pipelines 322 and 326. In this way, a complete refrigeration cycle is formed. The outdoor heat exchange fan 311 and the indoor heat exchange fans 320 and 324 may be adjusted respectively according to the indoor load of the data center computer room.

Further, driven by the indoor heat exchange fans 420 and 424, the heat passes through the indoor heat exchangers 421 and 425, then exchanges heat with the refrigerant evaporated after throttling, then flows out of the indoor heat exchange channels of the indoor heat exchangers 421 and 425, and then is sent to the computer room through the indoor air supply channel to cool the server clusters 01 and 02. The refrigerant gas evaporated in the indoor heat exchangers flows through the indoor heat exchanger return air pipelines 422 and 426, flows into the magnetic levitation compressor 413 through the main return air pipeline 435, then enters the first one-way valve 412 after compression, then enters the outdoor condenser air inlet pipeline 410, then passes through the outdoor heat exchanger air inlet pipelines 406 and 407 respectively, and then enters the outdoor finned heat exchangers 405 and 408. By adjusting the outdoor heat exchange fan 411, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 401 through the water pump 402 and then sends the pressurized water into the spray components 403 and 404, to cool the outdoor heat exchangers 405 and 408, respectively. The cooled refrigerant enters the main refrigerant liquid pipeline 409 through the outdoor heat exchanger liquid outlet pipeline. After being regulated and pressurized by the refrigerant circulating pump 417, the cooled refrigerant is sent through the refrigerant circulating pump liquid outlet pipe 418 to the electronic expansion valves 419 and 423 for throttling. The throttled refrigerant enters the indoor heat exchangers 421 and 425 for evaporation through the throttled refrigerant distribution pipeline again, and then the evaporated refrigerant enters the main return air pipeline 435 again through the return air pipelines 422 and 426. In this way, a complete refrigeration cycle is formed. The outdoor heat exchange fan 411 and the indoor heat exchange fans 420 and 424 may be adjusted respectively according to the indoor load of the data center computer room, to obtain the stable indoor target temperature, thereby reducing the power consumption of the outdoor and indoor heat exchange fans. The magnetic levitation centrifugal compressor only needs to work for a small amount of time in a high-temperature environment, thus saving energy consumption.

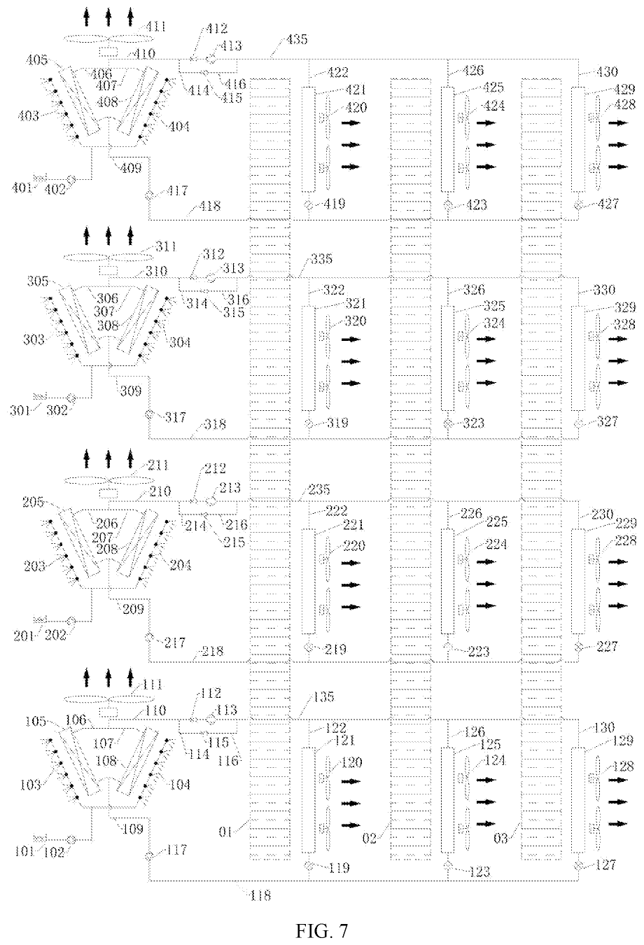

In one embodiment, reference is made to FIG. 7. The number of the servers in the server clusters 01, 02 and 03 from the data center computer room increases, and the heat generated by the servers also increases. Driven by the indoor heat exchange fans 120, 124 and 128, the heat passes through the indoor heat exchangers 121, 125 and 129, and exchanges heat with the refrigerant evaporated after throttling, then flows out of the indoor heat exchange channels of the indoor heat exchangers 121, 125 and 129, and then is sent to the computer room through the indoor air supply channel to cool the server clusters 01, 02, and 03. The refrigerant gas evaporated in the indoor heat exchangers flows through the indoor heat exchanger return air pipelines 122, 126 and 130, flows into the air inlet pipeline 116 and the second one-way valve 115 through the main return air pipeline 135, then flows into the outdoor condenser air inlet pipeline 110 through the pipeline 114, then passes through the outdoor heat exchanger air inlet pipelines 106 and 107 respectively, and enters the outdoor finned heat exchangers 105 and 108. By adjusting the outdoor heat exchange fan 111, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 101 through the water pump 102 and then sends the pressurized water into the spray components 103 and 104, to cool the outdoor heat exchangers 105 and 108, respectively. The cooled refrigerant enters the main refrigerant liquid pipeline 109 through the outdoor heat exchanger liquid outlet pipeline. After being regulated and pressurized by the refrigerant circulating pump 117, the cooled refrigerant is sent through the refrigerant circulating pump liquid outlet pipe 118 to the electronic expansion valves 119, 123 and 127 for throttling. The throttled refrigerant enters the indoor heat exchangers 121, 125 and 129 for evaporation through the throttled refrigerant distribution pipeline again, and then the evaporated refrigerant enters the main return air pipeline 135 again through the return air pipelines 122, 126 and 130. In this way, a complete refrigeration cycle is formed. The outdoor heat exchange fan 111 and the indoor heat exchange fans 120, 124 and 128 may be adjusted respectively according to the indoor load of the data center computer room.

Further, driven by the indoor heat exchange fans 220, 224 and 228, the heat passes through the indoor heat exchangers 221, 225 and 229, then exchanges heat with the refrigerant evaporated after throttling, then flows out of the indoor heat exchange channels of the indoor heat exchangers 221, 225 and 229, and then is sent to the computer room through the indoor air supply channel to cool the server clusters 01, 02 and 03. The refrigerant gas evaporated in the indoor heat exchangers flows through the indoor heat exchanger return air pipelines 222, 226 and 230, flows into the air inlet pipeline 216 and the second one-way valve 215 through the main return air pipeline 235, then flows into the outdoor condenser air inlet pipeline 210 through the pipeline 214, then passes through the outdoor heat exchanger air inlet pipelines 206 and 207 respectively, and enters the outdoor finned heat exchangers 205 and 208. By adjusting the outdoor heat exchange fan 211, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 201 through the water pump 202 and then sends the pressurized water into the spray components 203 and 204, to cool the outdoor heat exchangers 205 and 208, respectively. The cooled refrigerant enters the main refrigerant liquid pipeline 209 through the outdoor heat exchanger liquid outlet pipeline. After being regulated and pressurized by the refrigerant circulating pump 217, the cooled refrigerant is sent through the refrigerant circulating pump liquid outlet pipe 218 to the electronic expansion valves 219, 223 and 227 for throttling. The throttled refrigerant enters the indoor heat exchangers 221, 225 and 229 for evaporation through the throttled refrigerant distribution pipeline again, and then the evaporated refrigerant enters the main return air pipeline 235 again through the return air pipelines 222, 226 and 230. In this way, a complete refrigeration cycle is formed. The outdoor heat exchange fan 211 and the indoor heat exchange fans 220, 224 and 228 may be adjusted respectively according to the indoor load of the data center computer room.

Further, driven by the indoor heat exchange fans 320, 324 and 328, the heat passes through the indoor heat exchangers 321, 325 and 329, then exchanges heat with the refrigerant evaporated after throttling, then flows out of the indoor heat exchange channels of the indoor heat exchangers 321, 325 and 329, and then is sent to the computer room through the indoor air supply channel to cool the server clusters 01, 02 and 03. The refrigerant gas evaporated in the indoor heat exchangers flows through the indoor heat exchanger return air pipelines 322, 326 and 330, flows into the air inlet pipeline 316 and the second one-way valve 315 through the main return air pipeline 335, then flows into the outdoor condenser air inlet pipeline 310 through the pipeline 314, then passes through the outdoor heat exchanger air inlet pipelines 306 and 307 respectively, and enters the outdoor finned heat exchangers 305 and 308. By adjusting the outdoor heat exchange fan 311, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 301 through the water pump 302 and then sends the pressurized water into the spray components 303 and 304, to cool the outdoor heat exchangers 305 and 308, respectively. The cooled refrigerant enters the main refrigerant liquid pipeline 309 through the outdoor heat exchanger liquid outlet pipeline. After being regulated and pressurized by the refrigerant circulating pump 317, the cooled refrigerant is sent through the refrigerant circulating pump liquid outlet pipe 318 to the electronic expansion valves 319, 323 and 327 for throttling. The throttled refrigerant enters the indoor heat exchangers 321, 325 and 329 for evaporation through the throttled refrigerant distribution pipeline again, and then the evaporated refrigerant enters the main return air pipeline 335 again through the return air pipelines 322, 326 and 330. In this way, a complete refrigeration cycle is formed. The outdoor heat exchange fan 311 and the indoor heat exchange fans 320, 324 and 328 may be adjusted respectively according to the indoor load of the data center computer room.

Further, driven by the indoor heat exchange fans 420, 424 and 428, the heat passes through the indoor heat exchangers 421, 425 and 429, then exchanges heat with the refrigerant evaporated after throttling, then flows out of the indoor heat exchange channels of the indoor heat exchangers 421, 425 and 429, and then is sent to the computer room through the indoor air supply channel to cool the server clusters 01, 02 and 03. The refrigerant gas evaporated in the indoor heat exchangers flows through the indoor heat exchanger return air pipelines 422, 426 and 430, flows into the air inlet pipeline 416 and the second one-way valve 415 through the main return air pipeline 435, then flows into the outdoor condenser air inlet pipeline 410 through the pipeline 414, then passes through the outdoor heat exchanger air inlet pipelines 406 and 407 respectively, and enters the outdoor finned heat exchangers 405 and 408. By adjusting the outdoor heat exchange fan 411, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 401 through the water pump 402 and then sends the pressurized water into the spray components 403 and 404, to cool the outdoor heat exchangers 405 and 408, respectively. The cooled refrigerant enters the main refrigerant liquid pipeline 409 through the outdoor heat exchanger liquid outlet pipeline. After being regulated and pressurized by the refrigerant circulating pump 417, the cooled refrigerant is sent through the refrigerant circulating pump liquid outlet pipe 418 to the electronic expansion valves 419, 423 and 427 for throttling. The throttled refrigerant enters the indoor heat exchangers 421, 425 and 429 for evaporation through the throttled refrigerant distribution pipeline again, and then the evaporated refrigerant enters the main return air pipeline 435 again through the return air pipelines 422, 426 and 430. In this way, a complete refrigeration cycle is formed. The outdoor heat exchange fan 411 and the indoor heat exchange fans 420, 424 and 428 may be adjusted respectively according to the indoor load of the data center computer room, to obtain the stable indoor target temperature, thereby reducing the power consumption of the outdoor and indoor heat exchange fans. The required indoor target temperature can be obtained by means of natural cooling without starting the compressor, thus saving energy consumption.

Further, the number of the servers in the server clusters 01, 02 and 03 from the data center computer room increases, and heat generated by the servers also increases. Driven by the indoor heat exchange fans 120, 124 and 128, the heat passes through the indoor heat exchangers 121, 125 and 129, and exchanges heat with the refrigerant evaporated after throttling, then flows out of the indoor heat exchange channels of the indoor heat exchangers 121, 125 and 129, and then is sent to the computer room through the indoor air supply channel to cool the server clusters 01, 02 and 03. The refrigerant gas evaporated in the indoor heat exchangers flows through the indoor heat exchanger return air pipelines 122, 126 and 130, flows into the magnetic levitation compressor 113 through the main return air pipeline 135, then enters the first one-way valve 112 after compression, then enters the outdoor condenser air inlet pipeline 110, then passes through the outdoor heat exchanger air inlet pipelines 106 and 107 respectively, and then enters the outdoor finned heat exchangers 105 and 108. By adjusting the outdoor heat exchange fan 111, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 101 through the water pump 102 and then sends the pressurized water into the spray components 103 and 104, to cool the outdoor heat exchangers 105 and 108, respectively. The cooled refrigerant enters the main refrigerant liquid pipeline 109 through the outdoor heat exchanger liquid outlet pipeline. After being regulated and pressurized by the refrigerant circulating pump 117, the cooled refrigerant is sent through the refrigerant circulating pump liquid outlet pipe 118 to the electronic expansion valves 119, 123 and 127 for throttling. The throttled refrigerant enters the indoor heat exchangers 121, 125 and 129 for evaporation through the throttled refrigerant distribution pipeline again, and then the evaporated refrigerant enters the main return air pipeline 135 again through the return air pipelines 122, 126 and 130. In this way, a complete refrigeration cycle is formed. The outdoor heat exchange fan 111 and the indoor heat exchange fans 120, 124 and 128 may be adjusted respectively according to the indoor load of the data center computer room.

Further, driven by the indoor heat exchange fans 220, 224 and 228, the heat passes through the indoor heat exchangers 221, 225 and 229, then exchanges heat with the refrigerant evaporated after throttling, then flows out of the indoor heat exchange channels of the indoor heat exchangers 221, 225 and 229, and then is sent to the computer room through the indoor air supply channel to cool the server clusters 01, 02 and 03. The refrigerant gas evaporated in the indoor heat exchangers flows through the indoor heat exchanger return air pipelines 222, 226 and 230, flows into the magnetic levitation compressor 213 through the main return air pipeline 235, then enters the first one-way valve 212 after compression, then enters the outdoor condenser air inlet pipeline 210, then passes through the outdoor heat exchanger air inlet pipelines 206 and 207 respectively, and then enters the outdoor finned heat exchangers 205 and 208. By adjusting the outdoor heat exchange fan 211, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 201 through the water pump 202 and then sends the pressurized water into the spray components 203 and 204, to cool the outdoor heat exchangers 205 and 208, respectively. The cooled refrigerant enters the main refrigerant liquid pipeline 209 through the outdoor heat exchanger liquid outlet pipeline. After being regulated and pressurized by the refrigerant circulating pump 217, the cooled refrigerant is sent through the refrigerant circulating pump liquid outlet pipe 218 to the electronic expansion valves 219, 223 and 227 for throttling. The throttled refrigerant enters the indoor heat exchangers 221, 225 and 229 for evaporation through the throttled refrigerant distribution pipeline again, and then the evaporated refrigerant enters the main return air pipeline 235 again through the return air pipelines 222, 226 and 230. In this way, a complete refrigeration cycle is formed. The outdoor heat exchange fan 211 and the indoor heat exchange fans 220, 224 and 228 may be adjusted respectively according to the indoor load of the data center computer room.

Further, driven by the indoor heat exchange fans 320, 324 and 328, the heat passes through the indoor heat exchangers 321, 325 and 329, then exchanges heat with the refrigerant evaporated after throttling, then flows out of the indoor heat exchange channels of the indoor heat exchangers 321, 325 and 329, and then is sent to the computer room through the indoor air supply channel to cool the server clusters 01, 02 and 03. The refrigerant gas evaporated in the indoor heat exchangers flows through the indoor heat exchanger return air pipelines 322, 326 and 330, flows into the magnetic levitation compressor 313 through the main return air pipeline 335, then enters the first one-way valve 312 after compression, then enters the outdoor condenser air inlet pipeline 310, then passes through the outdoor heat exchanger air inlet pipelines 306 and 307 respectively, and then enters the outdoor finned heat exchangers 305 and 308. By adjusting the outdoor heat exchange fan 311, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 301 through the water pump 302 and then sends the pressurized water into the spray components 303 and 304, to cool the outdoor heat exchangers 305 and 308, respectively. The cooled refrigerant enters the main refrigerant liquid pipeline 309 through the outdoor heat exchanger liquid outlet pipeline. After being regulated and pressurized by the refrigerant circulating pump 317, the cooled refrigerant is sent through the refrigerant circulating pump liquid outlet pipe 318 to the electronic expansion valves 319, 323 and 327 for throttling. The throttled refrigerant enters the indoor heat exchangers 321, 325 and 329 for evaporation through the throttled refrigerant distribution pipeline again, and then the evaporated refrigerant enters the main return air pipeline 335 again through the return air pipelines 322, 326 and 330. In this way, a complete refrigeration cycle is formed. The outdoor heat exchange fan 311 and the indoor heat exchange fans 320, 324 and 328 may be adjusted respectively according to the indoor load of the data center computer room.

Further, driven by the indoor heat exchange fans 420, 424 and 428, the heat passes through the indoor heat exchangers 421, 425 and 429, then exchanges heat with the refrigerant evaporated after throttling, then flows out of the indoor heat exchange channels of the indoor heat exchangers 421, 425 and 429, and then is sent to the computer room through the indoor air supply channel to cool the server clusters 01, 02 and 03. The refrigerant gas evaporated in the indoor heat exchangers flows through the indoor heat exchanger return air pipelines 422, 426 and 430, flows into the magnetic levitation compressor 413 through the main return air pipeline 435, then enters the first one-way valve 412 after compression, then enters the outdoor condenser air inlet pipeline 410, then passes through the outdoor heat exchanger air inlet pipelines 406 and 407 respectively, and then enters the outdoor finned heat exchangers 405 and 408. By adjusting the outdoor heat exchange fan 411, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 401 through the water pump 402 and then sends the pressurized water into the spray components 403 and 404, to cool the outdoor heat exchangers 405 and 408, respectively. The cooled refrigerant enters the main refrigerant liquid pipeline 409 through the outdoor heat exchanger liquid outlet pipeline. After being regulated and pressurized by the refrigerant circulating pump 417, the cooled refrigerant is sent through the refrigerant circulating pump liquid outlet pipe 418 to the electronic expansion valves 419, 423 and 427 for throttling. The throttled refrigerant enters the indoor heat exchangers 421, 425 and 429 for evaporation through the throttled refrigerant distribution pipeline again, and then the evaporated refrigerant enters the main return air pipeline 435 again through the return air pipelines 422, 426 and 430. In this way, a complete refrigeration cycle is formed. The outdoor heat exchange fan 411 and the indoor heat exchange fans 420, 424 and 428 may be adjusted respectively according to the indoor load of the data center computer room, to obtain the stable indoor target temperature, thereby reducing the power consumption of the outdoor and indoor heat exchange fans. The magnetic levitation centrifugal compressor only needs to work for a small amount of time in a high-temperature environment, thus saving energy consumption.

In one embodiment, reference is made to FIG. 1. The number of the servers in the server clusters 01, 02, 03 and 04 from the data center computer room increases, and the heat generated by the servers also increases. Driven by the indoor heat exchange fans 120, 124, 128 and 132, the heat passes through the indoor heat exchangers 121, 125, 129 and 133, and exchanges heat with the refrigerant evaporated after throttling, then flows out of the indoor heat exchange channels of the indoor heat exchangers 121, 125, 129 and 133, and then is sent to the computer room through the indoor air supply channel to cool the server clusters 01, 02, 03, and 04. The refrigerant gas evaporated in the indoor heat exchangers flows through the indoor heat exchanger return air pipelines 122, 126, 130 and 134, flows into the air inlet pipeline 116 and the second one-way valve 115 through the main return air pipeline 135, then flows into the outdoor condenser air inlet pipeline 110 through the pipeline 114, then passes through the outdoor heat exchanger air inlet pipelines 106 and 107 respectively, and enters the outdoor finned heat exchangers 105 and 108. By adjusting the outdoor heat exchange fan 111, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 101 through the water pump 102 and then sends the pressurized water into the spray components 103 and 104, to cool the outdoor heat exchangers 105 and 108, respectively. The cooled refrigerant enters the main refrigerant liquid pipeline 109 through the outdoor heat exchanger liquid outlet pipeline. After being regulated and pressurized by the refrigerant circulating pump 117, the cooled refrigerant is sent through the refrigerant circulating pump liquid outlet pipe 118 to the electronic expansion valves 119, 123, 127, and 131 for throttling. The throttled refrigerant enters the indoor heat exchangers 121, 125, 129 and 133 for evaporation through the throttled refrigerant distribution pipeline again, and then the evaporated refrigerant enters the main return air pipeline 135 again through the return air pipelines 122, 126, 130, and 134. In this way, a complete refrigeration cycle is formed. The outdoor heat exchange fan 111 and the indoor heat exchange fans 120, 124, 128 and 132 may be adjusted respectively according to indoor load of the data center computer room.

Further, driven by the indoor heat exchange fans 220, 224, 228 and 232, the heat passes through the indoor heat exchangers 221, 225, 229 and 233, and exchanges heat with the refrigerant evaporated after throttling, then flows out of the indoor heat exchange channels of the indoor heat exchangers 221, 225, 229 and 233, and then is sent to the computer room through the indoor air supply channel to cool the server clusters 01, 02, 03, and 04. The refrigerant gas evaporated in the indoor heat exchangers flows through the indoor heat exchanger return air pipelines 222, 226, 230 and 234, flows into the air inlet pipeline 216 and the second one-way valve 215 through the main return air pipeline 235, then flows into the outdoor condenser air inlet pipeline 210 through the pipeline 214, then passes through the outdoor heat exchanger air inlet pipelines 206 and 207 respectively, and enters the outdoor finned heat exchangers 205 and 208. By adjusting the outdoor heat exchange fan 211, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 201 through the water pump 202 and then sends the pressurized water into the spray components 203 and 204, to cool the outdoor heat exchangers 205 and 208, respectively. The cooled refrigerant enters the main refrigerant liquid pipeline 209 through the outdoor heat exchanger liquid outlet pipeline. After being regulated and pressurized by the refrigerant circulating pump 217, the cooled refrigerant is sent through the refrigerant circulating pump liquid outlet pipe 218 to the electronic expansion valves 219, 223, 227, and 231 for throttling. The throttled refrigerant enters the indoor heat exchangers 221, 225, 229 and 233 for evaporation through the throttled refrigerant distribution pipeline again, and then the evaporated refrigerant enters the main return air pipeline 235 again through the return air pipelines 222, 226, 230, and 234. In this way, a complete refrigeration cycle is formed. The outdoor heat exchange fan 211 and the indoor heat exchange fans 220, 224, 228 and 232 may be adjusted respectively according to the indoor load of the data center computer room.

Further, driven by the indoor heat exchange fans 320, 324, 328 and 332, the heat passes through the indoor heat exchangers 321, 325, 329 and 333, and exchanges heat with the refrigerant evaporated after throttling, then flows out of the indoor heat exchange channels of the indoor heat exchangers 321, 325, 329 and 333, and then is sent to the computer room through the indoor air supply channel to cool the server clusters 01, 02, 03, and 04. The refrigerant gas evaporated in the indoor heat exchangers flows through the indoor heat exchanger return air pipelines 322, 326, 330 and 334, flows into the air inlet pipeline 316 and the second one-way valve 315 through the main return air pipeline 335, then flows into the outdoor condenser air inlet pipeline 310 through the pipeline 314, then passes through the outdoor heat exchanger air inlet pipelines 306 and 307 respectively, and enters the outdoor finned heat exchangers 305 and 308. By adjusting the outdoor heat exchange fan 311, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 301 through the water pump 302 and then sends the pressurized water into the spray components 303 and 304, to cool the outdoor heat exchangers 305 and 308, respectively. The cooled refrigerant enters the main refrigerant liquid pipeline 309 through the outdoor heat exchanger liquid outlet pipeline. After being regulated and pressurized by the refrigerant circulating pump 317, the cooled refrigerant is sent through the refrigerant circulating pump liquid outlet pipe 318 to the electronic expansion valves 319, 323, 327, and 331 for throttling. The throttled refrigerant enters the indoor heat exchangers 321, 325, 329 and 333 for evaporation through the throttled refrigerant distribution pipeline again, and then the evaporated refrigerant enters the main return air pipeline 335 again through the return air pipelines 322, 326, 330, and 334. In this way, a complete refrigeration cycle is formed. The outdoor heat exchange fan 311 and the indoor heat exchange fans 320, 324, 328 and 332 may be adjusted respectively according to indoor load of the data center computer room.

Further, driven by the indoor heat exchange fans 420, 424, 428 and 432, the heat passes through the indoor heat exchangers 421, 425, 429 and 433, and exchanges heat with the refrigerant evaporated after throttling, then flows out of the indoor heat exchange channels of the indoor heat exchangers 421, 425, 429 and 433, and then is sent to the computer room through the indoor air supply channel to cool the server clusters 01, 02, 03, and 04. The refrigerant gas evaporated in the indoor heat exchangers flows through the indoor heat exchanger return air pipelines 422, 426, 430 and 434, flows into the air inlet pipeline 416 and the second one-way valve 415 through the main return air pipeline 435, then flows into the outdoor condenser air inlet pipeline 410 through the pipeline 414, then passes through the outdoor heat exchanger air inlet pipelines 406 and 407 respectively, and enters the outdoor finned heat exchangers 405 and 408. By adjusting the outdoor heat exchange fan 411, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 401 through the water pump 402 and then sends the pressurized water into the spray components 403 and 404, to cool the outdoor heat exchangers 405 and 408, respectively. The cooled refrigerant enters the main refrigerant liquid pipeline 409 through the outdoor heat exchanger liquid outlet pipeline. After being regulated and pressurized by the refrigerant circulating pump 417, the cooled refrigerant is sent through the refrigerant circulating pump liquid outlet pipe 418 to the electronic expansion valves 419, 423, 427, and 431 for throttling. The throttled refrigerant enters the indoor heat exchangers 421, 425, 429 and 433 for evaporation through the throttled refrigerant distribution pipeline again, and then the evaporated refrigerant enters the main return air pipeline 435 again through the return air pipelines 422, 426, 430, and 434. In this way, a complete refrigeration cycle is formed. The outdoor heat exchange fan 411 and the indoor heat exchange fans 420, 424, 428 and 432 may be adjusted respectively according to the indoor load of the data center computer room, to obtain the stable indoor target temperature, thereby reducing the power consumption of the outdoor and indoor heat exchange fans. The required indoor target temperature can be obtained by means of natural cooling without starting the compressor, thus saving energy consumption.

Further, the number of the servers in the server clusters 01, 02, 03 and 04 from the data center computer room increases, and heat generated by the servers also increases. Driven by the indoor heat exchange fans 120, 124, 128 and 132, the heat passes through the indoor heat exchangers 121, 125, 129 and 133, and exchanges heat with the refrigerant evaporated after throttling, then flows out of the indoor heat exchange channels of the indoor heat exchangers 121, 125, 129 and 133, and then is sent to the computer room through the indoor air supply channel to cool the server clusters 01, 02, 03, and 04. The refrigerant gas evaporated in the indoor heat exchangers flows through the indoor heat exchanger return air pipelines 122, 126, 130 and 134, flows into the magnetic levitation compressor 113 through the main return air pipeline 135, then enters the first one-way valve 112 after compression, then enters the outdoor condenser air inlet pipeline 110, then passes through the outdoor heat exchanger air inlet pipelines 106 and 107 respectively, and then enters the outdoor finned heat exchangers 105 and 108. By adjusting the outdoor heat exchange fan 111, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 101 through the water pump 102 and then sends the pressurized water into the spray components 103 and 104, to cool the outdoor heat exchangers 105 and 108, respectively. The cooled refrigerant enters the main refrigerant liquid pipeline 109 through the outdoor heat exchanger liquid outlet pipeline. After being regulated and pressurized by the refrigerant circulating pump 117, the cooled refrigerant is sent through the refrigerant circulating pump liquid outlet pipe 118 to the electronic expansion valves 119, 123, 127, and 131 for throttling. The throttled refrigerant enters the indoor heat exchangers 121, 125, 129 and 133 for evaporation through the throttled refrigerant distribution pipeline again, and then the evaporated refrigerant enters the main return air pipeline 135 again through the return air pipelines 122, 126, 130, and 134. In this way, a complete refrigeration cycle is formed. The outdoor heat exchange fan 111 and the indoor heat exchange fans 120, 124, 128 and 132 may be adjusted respectively according to the indoor load of the data center computer room.

Further, driven by the indoor heat exchange fans 220, 224, 228 and 232, the heat passes through the indoor heat exchangers 221, 225, 229 and 233, and exchanges heat with the refrigerant evaporated after throttling, then flows out of the indoor heat exchange channels of the indoor heat exchangers 221, 225, 229 and 233, and then is sent to the computer room through the indoor air supply channel to cool the server clusters 01, 02, 03, and 04. The refrigerant gas evaporated in the indoor heat exchangers flows through the indoor heat exchanger return air pipelines 222, 226, 230 and 234, flows into the magnetic levitation compressor 213 through the main return air pipeline 235, then enters the first one-way valve 212 after compression, then enters the outdoor condenser air inlet pipeline 210, then passes through the outdoor heat exchanger air inlet pipelines 206 and 207 respectively, and then enters the outdoor finned heat exchangers 205 and 208. By adjusting the outdoor heat exchange fan 211, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 201 through the water pump 202 and then sends the pressurized water into the spray components 203 and 204, to cool the outdoor heat exchangers 205 and 208, respectively. The cooled refrigerant enters the main refrigerant liquid pipeline 209 through the outdoor heat exchanger liquid outlet pipeline. After being regulated and pressurized by the refrigerant circulating pump 217, the cooled refrigerant is sent through the refrigerant circulating pump liquid outlet pipe 218 to the electronic expansion valves 219, 223, 227, and 231 for throttling. The throttled refrigerant enters the indoor heat exchangers 221, 225, 229 and 233 for evaporation through the throttled refrigerant distribution pipeline again, and then the evaporated refrigerant enters the main return air pipeline 235 again through the return air pipelines 222, 226, 230, and 234. In this way, a complete refrigeration cycle is formed. The outdoor heat exchange fan 211 and the indoor heat exchange fans 220, 224, 228 and 232 may be adjusted respectively according to indoor load of the data center computer room.

Further, driven by the indoor heat exchange fans 320, 324, 328 and 332, the heat passes through the indoor heat exchangers 321, 325, 329 and 333, and exchanges heat with the refrigerant evaporated after throttling, then flows out of the indoor heat exchange channels of the indoor heat exchangers 321, 325, 329 and 333, and then is sent to the computer room through the indoor air supply channel to cool the server clusters 01, 02, 03, and 04. The refrigerant gas evaporated in the indoor heat exchangers flows through the indoor heat exchanger return air pipelines 322, 326, 330 and 334, flows into the magnetic levitation compressor 313 through the main return air pipeline 335, then enters the first one-way valve 312 after compression, then enters the outdoor condenser air inlet pipeline 310, then passes through the outdoor heat exchanger air inlet pipelines 306 and 307 respectively, and then enters the outdoor finned heat exchangers 305 and 308. By adjusting the outdoor heat exchange fan 311, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 301 through the water pump 302 and then sends the pressurized water into the spray components 303 and 304, to cool the outdoor heat exchangers 305 and 308, respectively. The cooled refrigerant enters the main refrigerant liquid pipeline 309 through the outdoor heat exchanger liquid outlet pipeline. After being regulated and pressurized by the refrigerant circulating pump 317, the cooled refrigerant is sent through the refrigerant circulating pump liquid outlet pipe 318 to the electronic expansion valves 319, 323, 327, and 331 for throttling. The throttled refrigerant enters the indoor heat exchangers 321, 325, 329 and 333 for evaporation through the throttled refrigerant distribution pipeline again, and then the evaporated refrigerant enters the main return air pipeline 335 again through the return air pipelines 322, 326, 330, and 334. In this way, a complete refrigeration cycle is formed. The outdoor heat exchange fan 311 and the indoor heat exchange fans 320, 324, 328 and 332 may be adjusted respectively according to indoor load of the data center computer room.

Further, driven by the indoor heat exchange fans 420, 424, 428 and 432, the heat passes through the indoor heat exchangers 421, 425, 429 and 433, and exchanges heat with the refrigerant evaporated after throttling, then flows out of the indoor heat exchange channels of the indoor heat exchangers 421, 425, 429 and 433, and then is sent to the computer room through the indoor air supply channel to cool the server clusters 01, 02, 03, and 04. The refrigerant gas evaporated in the indoor heat exchangers flows through the indoor heat exchanger return air pipelines 422, 426, 430 and 434, flows into the magnetic levitation compressor 413 through the main return air pipeline 435, then enters the first one-way valve 412 after compression, then enters the outdoor condenser air inlet pipeline 410, then passes through the outdoor heat exchanger air inlet pipelines 406 and 407 respectively, and then enters the outdoor finned heat exchangers 405 and 408. By adjusting the outdoor heat exchange fan 411, the refrigerant in the outdoor heat exchangers is cooled, and the heat of the refrigerant is discharged into the atmosphere, such that the cooled refrigerant changes from the gas to the liquid. Further, the spray cooling system pressurizes the water in the water tank 401 through the water pump 402 and then sends the pressurized water into the spray components 403 and 404, to cool the outdoor heat exchangers 405 and 408, respectively. The cooled refrigerant enters the main refrigerant liquid pipeline 409 through the outdoor heat exchanger liquid outlet pipeline. After being regulated and pressurized by the refrigerant circulating pump 417, the cooled refrigerant is sent through the refrigerant circulating pump liquid outlet pipe 418 to the electronic expansion valves 419, 423, 427, and 431 for throttling. The throttled refrigerant enters the indoor heat exchangers 421, 425, 429 and 433 for evaporation through the throttled refrigerant distribution pipeline again, and then the evaporated refrigerant enters the main return air pipeline 435 again through the return air pipelines 422, 426, 430, and 434. In this way, a complete refrigeration cycle is formed. The outdoor heat exchange fan 411 and the indoor heat exchange fans 420, 424, 428 and 432 may be adjusted respectively according to the indoor load of the data center computer room, to obtain the stable indoor target temperature, thereby reducing the power consumption of the outdoor and indoor heat exchange fans. The magnetic levitation centrifugal compressor only needs to work for a small amount of time in a high-temperature environment, thus saving energy consumption.

The air-conditioning system for the data center computer room achieved according to the above invention method can ensure temperature, humidity, and quality requirements of the air in the data center computer room, meet precise control of the air temperature inside the data center computer room, and maximize the utilization of natural energy resources, thus saving energy. There is no need for consumption of water resources.

The above embodiments merely express embodiments of the present disclosure, and descriptions thereof are relatively concrete and detailed. However, these embodiments are not thus construed as limiting the patent scope of the present disclosure. It is to be pointed out that for persons of ordinary skill in the art, some modifications and improvements may be made under the premise of not departing from a conception of the present disclosure, which shall be regarded as falling within the scope of protection of the present disclosure. Thus, the scope of protection of the present disclosure shall be merely limited by the appended claims.

The present disclosure carries out modular management on the air-conditioning system for the data center computer room, which can provide cold sources according to actual heat dissipation needs of different areas of the data center computer room, flexibly and accurately allocate refrigeration capacity, and meet requirements of business volume changes in the servers of the computer room. Consumption of water resources can be reduced by means of spray cooling. Energy can be saved by cooling the servers using natural cooling sources. Each refrigeration subsystem operates independently and serves as mutual standby, which can reduce a risk of server outage and improve reliability of operation of the computer room. Temperature of each row of servers can be independently controlled to eliminate hotspots in the computer room. A refrigeration terminal is independently arranged for easy maintenance.

Based on the same technical idea, the embodiments of the present disclosure also provide a control method for an air-conditioning system for a data center computer room, where the control method is applied to the air-conditioning system for the data center computer room described in the first aspect. The control method includes:
determining a refrigeration mode based on an indoor ambient temperature of the data center computer room, where the refrigeration mode includes a natural refrigeration mode and a mechanical refrigeration mode;
determining number of the refrigeration subsystems based on a size of each of the server clusters; and
determining number of the indoor heat exchange modules in each of the refrigeration subsystems based on number of the server clusters.

Further, the determining a refrigeration mode based on an indoor ambient temperature of the data center computer room includes:
enabling the natural refrigeration mode when the indoor ambient temperature of the data center is not higher than a preset temperature threshold; and
enabling the mechanical refrigeration mode when the indoor ambient temperature of the data center is higher than the preset temperature threshold in the natural refrigeration mode.

Further, the determining number of the refrigeration subsystems based on a size of each of the server clusters includes:
increasing the number of the refrigeration subsystems when number of servers in a target server cluster increases.

Further, the determining number of the indoor heat exchange modules in each of the refrigeration subsystems based on number of the server clusters includes:
increasing the number of the indoor heat exchange modules connected in parallel in each of the refrigeration subsystems when the number of the server clusters increases.

By adopting the air-conditioning system for the data center computer room and the control method thereof, the present disclosure can at least produce the following technical effects.

The present disclosure carries out modular management on the air-conditioning system for the data center computer room, which can provide cold sources according to actual heat dissipation needs of different areas of the data center computer room, flexibly and accurately allocate refrigeration capacity, and meet requirements of business volume changes in the servers of the computer room. Consumption of water resources can be reduced by means of spray cooling. Energy can be saved by cooling the servers using natural cooling sources. Each refrigeration subsystem operates independently and serves as mutual standby, which can reduce a risk of server outage and improve reliability of operation of the computer room. Temperature of each row of servers can be independently controlled to eliminate hotspots in the computer room. A refrigeration terminal is independently arranged for easy maintenance.

The embodiments described above are merely preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. An air-conditioning system for a data center computer room, comprising one or more refrigeration subsystems and one or more server clusters; wherein
pipelines of each of the refrigeration subsystem are independent of each other; and
each of the refrigeration subsystems comprises at least one outdoor refrigeration module and a plurality of indoor heat exchange modules respectively arranged in the server clusters, and the plurality of indoor heat exchange modules are connected in parallel through the pipelines.

2. The air-conditioning system for the data center computer room as claimed in claim 1, wherein the at least one outdoor refrigeration module comprises: a spray cooling unit, an outdoor heat exchange unit, a mechanical refrigeration unit, and an outdoor fan;
the outdoor heat exchange unit is connected to the mechanical refrigeration unit through the pipelines;
the spray cooling unit is arranged adjacent to an outer side of the outdoor heat exchange unit; and
the outdoor fan is arranged at an air outlet of the outdoor heat exchange unit.

3. The air-conditioning system for the data center computer room as claimed in claim 2, wherein the mechanical refrigeration unit comprises a compressor, a first branch one-way valve, and a second branch one-way valve, the compressor being connected in series with the first branch one-way valve through the pipelines to form a compressor set, and the second branch one-way valve being connected in parallel with the compressor set through the pipelines.

4. The air-conditioning system for the data center computer room as claimed in claim 3, wherein the compressor is a magnetic levitation compressor.

5. The air-conditioning system for the data center computer room as claimed in claim 1, wherein the indoor heat exchange module comprises an indoor heat exchanger and an indoor fan;
an inlet pipeline and an outlet pipeline of the indoor heat exchanger are respectively connected to an outlet pipeline and an inlet pipeline of the outdoor refrigeration module; and
the indoor fan is arranged at an indoor air channel of the data center computer room.

6. The air-conditioning system for the data center computer room as claimed in claim 5, wherein an electronic expansion valve is connected to the inlet pipeline or the outlet pipeline of the indoor heat exchanger.

7. A control method for an air-conditioning system for a data center computer room, wherein the control method is applied to the air-conditioning system for the data center computer room, the air-conditioning system for the data center computer room comprises one or more refrigeration subsystems and one or more server clusters; wherein
pipelines of each of the refrigeration subsystem are independent of each other; and
each of the refrigeration subsystems comprises at least one outdoor refrigeration module and a plurality of indoor heat exchange modules respectively arranged in the server clusters, and the plurality of indoor heat exchange modules are connected in parallel through the pipelines, and
the control method comprises:
determining a refrigeration mode based on an indoor ambient temperature of the data center computer room, wherein the refrigeration mode comprises a natural refrigeration mode and a mechanical refrigeration mode;
determining number of the refrigeration subsystems based on a size of each of the server clusters; and
determining number of the indoor heat exchange modules in each of the refrigeration subsystems based on number of the server clusters.

8. The control method as claimed in claim 7, wherein the determining a refrigeration mode based on an indoor ambient temperature of the data center computer room comprises:
enabling the natural refrigeration mode when the indoor ambient temperature of the data center is not higher than a preset temperature threshold; and
enabling the mechanical refrigeration mode when the indoor ambient temperature of the data center is higher than the preset temperature threshold in the natural refrigeration mode.

9. The control method as claimed in claim 7, wherein the determining number of the refrigeration subsystems based on a size of each of the server clusters comprises:
increasing the number of the refrigeration subsystems when number of servers in a target server cluster increases.

10. The control method as claimed in claim 7, wherein the determining number of the indoor heat exchange modules in each of the refrigeration subsystems based on number of the server clusters comprises:
increasing the number of the indoor heat exchange modules connected in parallel in each of the refrigeration subsystems when the number of the server clusters increases.
